(19) United States
(12) Patent Application Publication
(10) Pub. No.: US 2015/0179615 A1
(43) Pub. Date: Jun. 25, 2015

(54) SEMICONDUCTOR DEVICE AND METHOD FOR MANUFACTURING THE SAME

(71) Applicants: Shinji WATANABE, Kanagawa (JP); Tsuyoshi KIDA, Kanagawa (JP); Yoshihiro ONO, Kanagawa (JP); Kentaro MORI, Kanagawa (JP); Kenji SAKATA, Kanagawa (JP); Yusuke YAMADA, Kanagawa (JP)

(72) Inventors: Shinji WATANABE, Kanagawa (JP); Tsuyoshi KIDA, Kanagawa (JP); Yoshihiro ONO, Kanagawa (JP); Kentaro MORI, Kanagawa (JP); Kenji SAKATA, Kanagawa (JP); Yusuke YAMADA, Kanagawa (JP)

(21) Appl. No.: 14/557,644

(22) Filed: Dec. 2, 2014

(30) Foreign Application Priority Data
Dec. 24, 2013 (JP) 2013-266050

(51) Int. Cl. H01L 25/065; H01L 23/00; H01L 21/78; H01L 25/00

(52) U.S. Cl. CPC H01L 25/0657; H01L 25/50; H01L 24/94; H01L 24/81; H01L 24/17; H01L 21/78; H01L 2225/06517; H01L 2225/06513; H01L 2924/014; H01L 2224/13147; H01L 2224/13155; H01L 2224/13111; H01L 2924/2064; H01L 2224/16145; H01L 2224/16227; H01L 2224/81801; H01L 2924/20106; H01L 2224/812

(57) ABSTRACT

To improve reliability of a semiconductor device. In a conductive material that electrically couples a Cu pillar electrode and a lead, an alloy part comprised of an alloy of tin and copper is formed inside this conductive material. At this time, the alloy part contacts both the Cu pillar electrode and the lead, and the Cu pillar electrode and the lead are bound through the alloy part. Similarly, also in FIG. 8, it is found that the Cu pillar electrode and the lead are electrically coupled to each other by the alloy part. Thereby, it is possible to improve electric coupling reliability between the Cu pillar electrode and the lead.

### CROSS-REFERENCE TO RELATED APPLICATIONS

The disclosure of Japanese Patent Application No. 2013-266050 filed on Dec. 24, 2013 including the specification, drawings and abstract is incorporated herein by reference in its entirety.

### BACKGROUND

The present invention relates to a semiconductor device and a manufacturing technology thereof, for example, relates to a semiconductor device in which a protrusion electrode formed in a semiconductor chip and an electrode formed over a substrate are electrically coupled to each other through a conductive material and a manufacturing technology thereof.

Japanese Unexamined Patent Application Publication No. 2013-48285 describes that copper of which a coupling pad of a wiring board is comprised and tin (Sn) contained in a solder bump electrode form a firmer copper-tin alloy compared with a nickel-tin alloy. Moreover, Japanese Unexamined Patent Application Publication No. 2013-48285 describes that mounting body such that a semiconductor chip is mounted over the wiring board is subjected to a bake treatment in nitrogen atmosphere at a temperature of 115° C. to 125° C. for one hour.

Japanese Unexamined Patent Application Publication No. 2009-152317 describes that a mounting body such that a semiconductor chip is mounted over a wiring board is subjected to a bake treatment in a nitrogen atmosphere at a temperature of 115° C. to 125° C. for one hour.

Japanese Unexamined Patent Application Publication No. Hei11 (1999)-154688 describes that a wiring electrode and a bump electrode that are provided over a ceramic wiring board are coupled to each other and a semiconductor element is mounted over the wiring board. Then, this patent document further describes that a conductive resin is hardened by heating it at 100° C. for two hours through a heating process to form a coupling part, subsequently the wiring board is placed on a stage while keeping a high temperature state of 100° C., and a sealing resin is applied over the wiring board that is adjacent to an upper side of the semiconductor element with a dispenser.

### SUMMARY

For example, as one mode of a semiconductor device (package), there is a structure where a projection electrode (bump electrode) formed in a semiconductor chip and an electrode formed over a substrate are coupled through conductive material represented by solder. In a manufacturing process of the semiconductor device having the structure described above, usually a heating process of adding a heat treatment after a coupling process of the projection electrode and the electrode exists, and a temperature may exceed a melting point of the conductive material depending on the heating process. In this case, although the conductive material will be remelted, the present inventors have found that when the conductive material is remelted, a phenomenon in which a part of the remelted conductive material creeps up a side face of the projection electrode and a phenomenon in which it flows along the electrode of the substrate arise.

When such phenomena arise, a quantity of the conductive material that contributes to coupling between the projection electrode and the electrode decreases, and as a result, there is a possibility that it may result in a decline in coupling reliability between the projection electrode and the electrode and a deterioration of electrical properties themselves due to an increase in conduction resistance. That is, in the one mode of the present semiconductor device, there is a room for improvement from the viewpoint of improving coupling reliability between the projection electrode and the electrode and from the viewpoint of securing stable electrical properties.

Other problems and new features will become clear from description and accompanying drawings of this specification.

In a semiconductor device in one embodiment, an alloy part is formed in a conductive material that electrically couples a projection electrode and an electrode, the alloy part contacts both the projection electrode and the electrode, and the projection electrode and the electrode are bound through the alloy part.

According to the one embodiment, the electrical properties of the semiconductor device can be stabilized, and thereby it is possible to improve reliability of the semiconductor device.

### BRIEF DESCRIPTION OF THE DRAWINGS

FIG. 1 is a sectional view showing a schematic configuration of a semiconductor device in a first embodiment;

FIG. 2 is a schematic diagram showing a configuration example of a lead formed over an upper surface of a wiring board;

FIG. 3 is a sectional view cut by a line A-A of FIG. 2;

FIG. 4 is a sectional view cut by a line B-B of FIG. 2;

FIG. 5 is a schematic diagram corresponding to FIG. 3, and is a diagram showing a state after a conductive material is remelted;

FIG. 6 is a schematic diagram corresponding to FIG. 4, and is a diagram showing a state after the conductive material is remelted;

FIG. 7 is a diagram showing a characteristic of the first embodiment, and is a diagram corresponding to the sectional view cut by the line A-A of FIG. 2;

FIG. 8 is a diagram showing a characteristic of this first embodiment, and is a diagram corresponding to the sectional view cut by the line B-B of FIG. 2;

FIG. 9 is a schematic diagram showing a state where a heat treatment is applied after a configuration shown in FIG. 7 is formed;

FIG. 10 is a schematic diagram showing a state where a heat treatment is applied after a configuration shown in FIG. 8 is formed;

FIGS. 11A to 11C are schematic diagrams each showing one example of a mode of an alloy part in the first embodiment, respectively;

FIGS. 12A to 12C are schematic diagram each showing one example of a configuration mode of a coupling part, respectively;

FIG. 13 is a schematic diagram showing one example of a configuration mode of the coupling part;

FIG. 14 is a schematic diagram showing one example of the configuration mode of the coupling part;

FIGS. 15A to 15D are schematic diagrams each showing one example of a configuration mode of a Cu pillar electrode, respectively;

FIGS. 16A to 16E are schematic diagrams each showing one example of a configuration mode of a lead, respectively;

FIG. 17 is a flowchart showing a flow of a manufacturing process of the semiconductor device in the first embodiment;

FIG. 18 is a diagram for explaining a first example of a flip-chip mounting process;

FIG. 19 is a diagram for explaining a second example of the flip-chip mounting process;

FIG. 20 is a diagram for explaining a third example of the flip-chip mounting process;

FIG. 21 is a diagram for explaining a fourth example of the flip-chip mounting process;

FIG. 22 is a sectional view showing a condition where the semiconductor chip is flip-chip mounted over a wiring board;

FIG. 23 is a sectional view showing a condition where the alloy part is formed in the conductive material by an alloying heat treatment that is a characteristic process of the first embodiment;

FIG. 24 is a sectional view showing a schematic configuration of a semiconductor device in a second embodiment;

FIG. 25 is a flowchart showing a flow of a manufacturing process of the semiconductor device in the second embodiment;

FIG. 26 is a diagram for explaining a first example of second flip-chip mounting process;

FIG. 27 is a diagram for explaining a second example of the second flip-chip mounting process;

FIG. 28 is a schematic plan view showing an arrangement relationship among a solder resist formed over the wiring board, a land comprised of SMD formed over the wiring board, and the Cu pillar electrode formed in the semiconductor chip;

FIG. 29 is a sectional view cut by the line A-A of FIG. 28;

FIG. 30 is a schematic diagram corresponding to FIG. 29, and is a diagram showing a state after the conductive material is remelted;

FIG. 31 is a sectional view for explaining an aspect (SMD) of a third embodiment;

FIG. 32 is a schematic plan view showing an arrangement relationship among the solder resist formed over the wiring board, the land comprised of the SMD formed over the wiring board, and the Cu pillar electrode formed in the semiconductor chip;

FIG. 33 is a sectional view cut by the line A-A of FIG. 32;

FIG. 34 is a schematic diagram corresponding to FIG. 33, and is a diagram showing a state after the conductive material is remelted; and

FIG. 35 is a sectional view for explaining the aspect (NSMD) of the third embodiment.

### DETAILED DESCRIPTION

In the following embodiments, when there is a necessity for convenience, they are divided into multiple sections or embodiments and explanations are given to them. However, they are not mutually irrelevant, and one section or embodiment is in a relationship of a modification, an application example, a detailed explanation, a supplementary explanation, etc. of part or the whole of the other section or embodiment, except for the case where it is specifically indicated.

Moreover, in the following embodiments, when referring to the number of components etc. (including a number, a numerical value, a quantity, a range, etc.), the number is not limited to the specific number and may be more than or less than the specific number except for the case where it is specifically indicated, the case where it is clearly limited to the specific number fundamentally, and the like.

Furthermore, in the following embodiments, it goes without saying that their components (including an element step, etc.) are not necessarily indispensable except for the case where it is specifically indicated, the case where it is considered clearly indispensable fundamentally that it is clearly indispensable, and the like.

Similarly, in the following embodiment, when referring to a shape, a positional relationship, etc. of the component, etc., it shall include one that is substantially approximate or analogous to its shape, etc. except for the case where it is specifically indicated, the case where it is considered clearly not so theoretically, and the like. This is the same also about the above-mentioned numerical value and range.

Moreover, in all diagrams for explaining the embodiments, the same reference numeral is given to the same member in principle, and its repeated explanation is omitted. Incidentally, a drawing even in the case of a plan view may be hatched in order to make the drawing comprehensible.

### First Embodiment

### Configuration of Semiconductor Device

For example, a semiconductor device is formed with a semiconductor chip in which a semiconductor element such as a metal oxide semiconductor field effect transistor (MOSFET) and multilayer interconnection are formed and a package formed so as to cover this semiconductor chip. The package has: (1) a function of electrically coupling the semiconductor element formed in the semiconductor chip and an external circuit; and (2) a function of protecting the semiconductor chip from external environments such as humidity and temperature and preventing breakage from vibration and shock and characteristic degradation of the semiconductor chip. Furthermore, the package has: (3) a function of making handling of the semiconductor chips easy; and (4) a function of diffusing generation of heat at the time of an operation of the semiconductor chip and making the semiconductor element demonstrate its function to a maximum extent; etc. Although various kinds exist in the package that has such functions, especially in this first embodiment, a ball grid array (BGA) will be taken as one example of a package mode and explained.

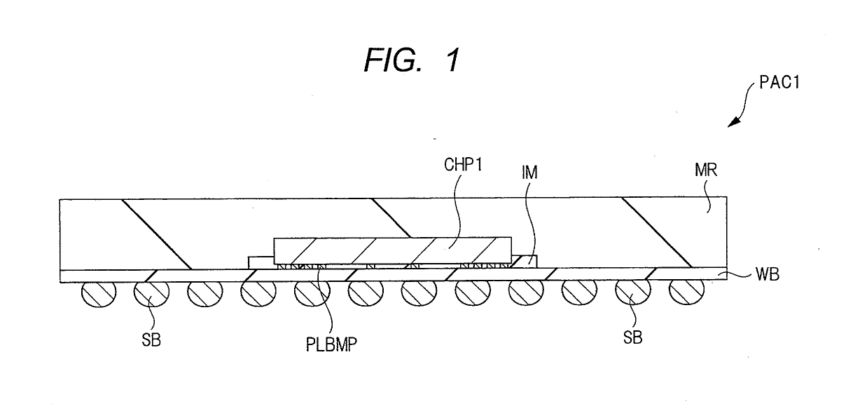

FIG. 1 is a sectional view showing a schematic configuration of a semiconductor device PAC1 in this first embodiment. In FIG. 1, the semiconductor device PAC1 in this first embodiment has a wiring board WB inside which the multilayer interconnection is formed, for example, and a semiconductor chip. CHP1 is mounted over an upper surface (surface, main, plane) of this wiring board WB. On the other hand, multiple solder balls SB that will be electrically coupled with the multilayer interconnection formed in the inside of the wiring board WB are provided over an undersurface (rear surface) of the wiring board WB. Each of these multiple solder balls SB will function as an external coupling terminal that electrically couples the semiconductor device PAC1 and an external device.

For example, by establishing electrical coupling between a lead (electrode) formed over an upper surface of the wiring board WB (not shown in FIG. 1) and a Cu pillar electrode (projection electrode) PLBMP formed in the semiconductor chip CHP1, the semiconductor chip CHP1 and the wiring board WB will be electrically coupled to each other. Here, the Cu pillar electrode PLBMP formed in the semiconductor chip CHP1 is comprised of, for example, a material containing copper, and the lead formed over the wiring board WB is also comprised of a material containing copper.

In the semiconductor chip CHP1, for example, a field-effect transistor (MOSFET), passive elements represented by a resistance element, a capacitor, and an inductor, and wiring are formed, and an integrated circuit is formed by combination of the multiple field-effect transistors, the passive elements, and the wiring. Therefore, the integrated circuit formed in the semiconductor chip CHP1 will be electrically coupled with the external device provided in the outside of the semiconductor device PAC1 through the Cu pillar electrode PLBMP→the lead→the multilayer interconnection of the wiring board WB→solder balls SB.

Next, as shown in FIG. 1, an insulating resin material IM is filled in a gap between the semiconductor chip CHP1 and the wiring board WB, and further a sealing body MR that covers the semiconductor chip CHP1 is provided over the wiring board WB.

Although the semiconductor device PAC1 in this first embodiment is formed as described above, the present inventors have revealed that in the semiconductor device PAC1 having such a configuration, a room for improvement exists from the viewpoint of improving reliability of the semiconductor device PAC1. Below this room for improvement will be explained, and subsequently, a characteristic point of this first embodiment on which contrivances for this room for improvement is performed will be explained.

### <Room for Improvement>

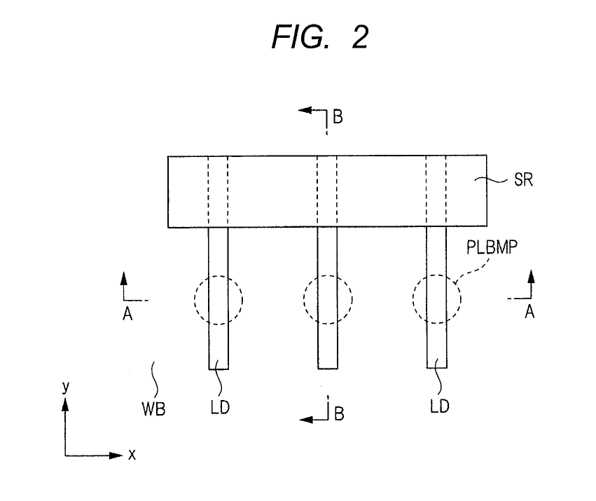

FIG. 2 is a schematic diagram showing a configuration example of a lead LD that is formed over the upper surface of the wiring board WB. As shown in FIG. 2, over the upper surface of the wiring board WB, the multiple leads LD extending in a y-direction shown in FIG. 2 are arranged side by side with a predetermined spacing in an x-direction. Then, as shown in FIG. 2, solder resist SR is formed over the upper surface of the wiring board WB over which the lead LD is formed, and there exist a portion covered with the solder resist SR and a portion exposed from the solder resist SR in the lead LD. At this time, the semiconductor device PAC1 in this first embodiment is configured so that the Cu pillar electrode PLBMP formed in the semiconductor chip may be coupled to a portion of the lead LD exposed from the solder resist SR.

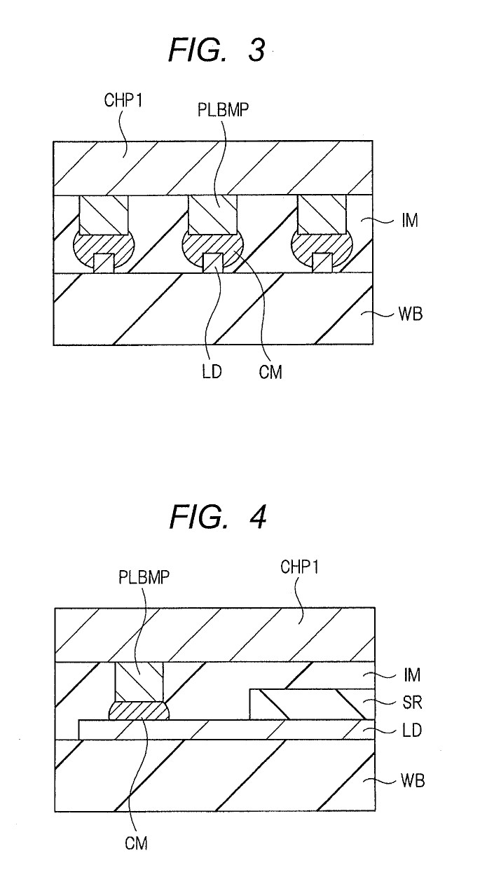

FIG. 3 is a sectional view cut by a line A-A of FIG. 2. As shown in FIG. 3, the leads LD are formed over the upper surface of the wiring board WB, and the Cu pillar electrodes formed in the semiconductor chip CHP1 are arranged so as to face these leads LD. Then, the lead LD and the Cu pillar electrode PLBMP are electrically coupled to each other, for example, through a conductive material CM comprised of solder containing tin. Furthermore, the insulating resin material IM is formed so as to fill the gap between the semiconductor chip CHP1 and the wiring board WB.

FIG. 4 is a sectional view cut by a line B-B of FIG. 2. As shown in FIG. 3, the lead LD is formed over the upper surface of the wiring board WB, and it is found that one part of this lead LD is covered with the solder resist SR and the other part of the lead LD is exposed from the solder resist SR. Then, the Cu pillar electrode PLBMP formed in the semiconductor chip CHP1 is arranged above the portion of the lead LD exposed from the solder resist SR, and this Cu pillar electrode PLBMP and the lead LD are electrically coupled to each other by the conductive material CM. Furthermore, the insulating resin material IM is filled between the semiconductor chip CHP1 and the wiring board WB.

In the semiconductor device PAC1 in this first embodiment thus configured, as shown in FIG. 3 and FIG. 4, the Cu pillar electrode PLBMP and the lead LD are electrically coupled to each other, for example, by the conductive material CM comprised of the solder containing tin. Here, in this first embodiment, as shown in FIG. 1, for example, the solder balls SB are formed over a rear surface of the wiring board WB, and a process of forming these solder balls SB is performed after the above-mentioned process of coupling the Cu pillar electrode PLBMP and the lead LD with the conductive material CM. Then, in a process of forming the solder balls SB, melting of the solder balls SB is performed by a heat treatment process called solder reflow. Therefore, the conductive material CM that couples the Cu pillar electrode PLBMP and the lead LD will be remelted by the solder reflow performed in the process of forming the solder balls SB.

Moreover, after the semiconductor device PAC1 is completed as a product, it will be mounted over a motherboard. At this time, the following process is performed: the solder balls SB formed in the semiconductor device PAC1 is melted by the solder reflow; and the solder balls SB formed in the semiconductor device PAC1 and the electrode formed over the motherboard are electrically coupled to each other.

From this, for example, the conductive material CM that couples the Cu pillar electrode PLBMP and the lead LD will be remelted by a subsequent heat treatment that is represented by the solder reflow at the time of forming the solder balls and the solder reflow at the time of mounting the semiconductor device PAC1 over the motherboard. When such remelting of the conductive material CM arises, there is a possibility that coupling reliability between the Cu pillar electrode PLBMP and the lead LD may decline, or an electric resistance may increase.

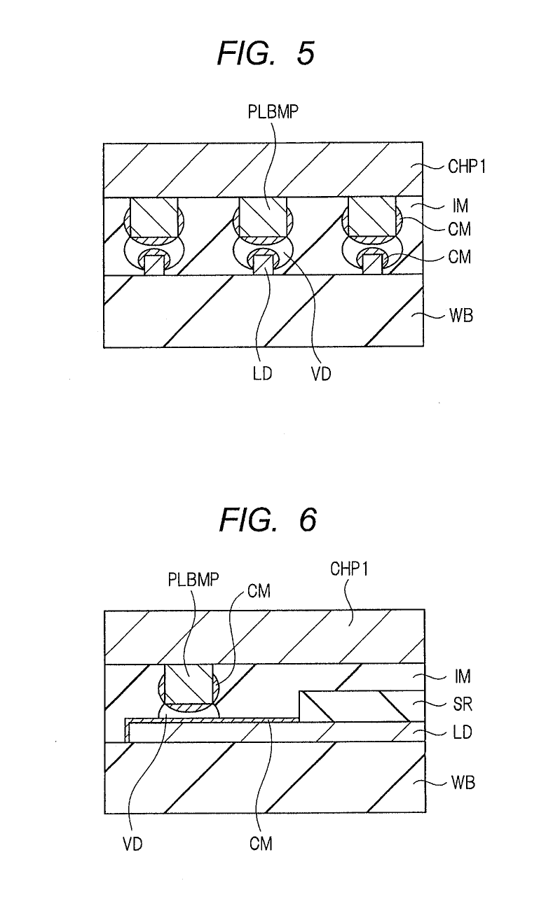

Below, this point will be explained. FIG. 5 is a schematic diagram corresponding to FIG. 3, and is a diagram showing a state after the conductive material CM is remelted. As shown in FIG. 5, when the conductive material CM that electrically couples the Cu pillar electrode PLBMP and the lead LD is remelted, a phenomenon in which the conductive material CM that became the liquid creeps up a side face of the Cu pillar electrode PLBMP arises (first mechanism). As a result, a part of the conductive material CM that electrically couples the Cu pillar electrode PLBMP and the lead LD will be used for creeping up to the side face of the Cu pillar electrode PLBMP, and therefore a quantity of the conductive material CM formed between the Cu pillar electrode PLBMP and the lead LD decreases. From this, as, shown in FIG. 5, for example, it is conceivable that a void VD occurs between the Cu pillar electrode PLBMP and the lead LD. When such a void VD occurs, electric coupling between the Cu pillar electrode PLBMP and the lead LD will be inhibited by the void VD, and there is a possibility that the electric resistance may increase between the Cu pillar electrode PLBMP and the lead LD, or open failure may occur.

Furthermore, FIG. 6 is a schematic diagram corresponding to FIG. 4, and is a diagram showing a state after the conductive material CM is remelted. As shown in FIG. 6, when the conductive material CM that electrically couples the Cu pillar electrode PLBMP and the lead LD is remelted, a phenomenon in which the conductive material CM that became the liquid gets wet and spreads onto a surface of the lead LD exposed from the solder resist SR arises (second mechanism). As a result, a part of the conductive material CM that electrically couples the Cu pillar electrode PLBMP and the lead LD will be used for getting wet and spreading onto the surface of the lead LD that is exposed from the solder resist SR, and therefore, the quantity of the conductive material CM formed between the Cu pillar electrode PLBMP and the lead LD decreases. Especially, since formation precision of the solder resist SR is comparatively low, in order that a coupling region of the Cu pillar electrode PLBMP and the lead LD is not covered with the solder resist SR due to formation displacement of the solder resist SR, an end of the solder resist SR is sufficiently separated from the coupling region of the Cu pillar electrode PLBMP and the lead LD. Therefore, an area of the portion of the lead LD exposed from the solder resist SR becomes large, and this increases the quantity of the conductive material CM that gets wet and spreads onto the surface of the lead LD exposed from the solder resist SR. This means that the quantity of the conductive material CM formed between the Cu pillar electrode PLBMP and the lead LD decreases considerably.

From the above, when the conductive material CM that electrically couples the Cu pillar electrode PLBMP and the lead LD is remelted, there is a possibility that the open failure may occur between the Cu pillar electrode PLBMP and the lead LD by the first mechanism and the second mechanism that were described above. In other words, it is apprehended that when the conductive material. CM that electrically couples the Cu pillar electrode PLBMP and the lead LD is remelted, electric coupling reliability between the Cu pillar electrode PLBMP and the lead. LD declines. That is, in the semiconductor device PACT, it is found that the room for improvement exists from the viewpoint of improving the electric coupling reliability between the Cu pillar electrode PLBMP and the lead LD and from the viewpoint of securing electrical properties. Thereupon, in this first embodiment, a contrivance to improve the electric coupling reliability between the Cu pillar electrode PLBMP and the lead LD and a contrivance to secure the electrical properties are given. Below; a technical idea in this first embodiment to which these contrivances are given will be explained.

### Feature in this First Embodiment

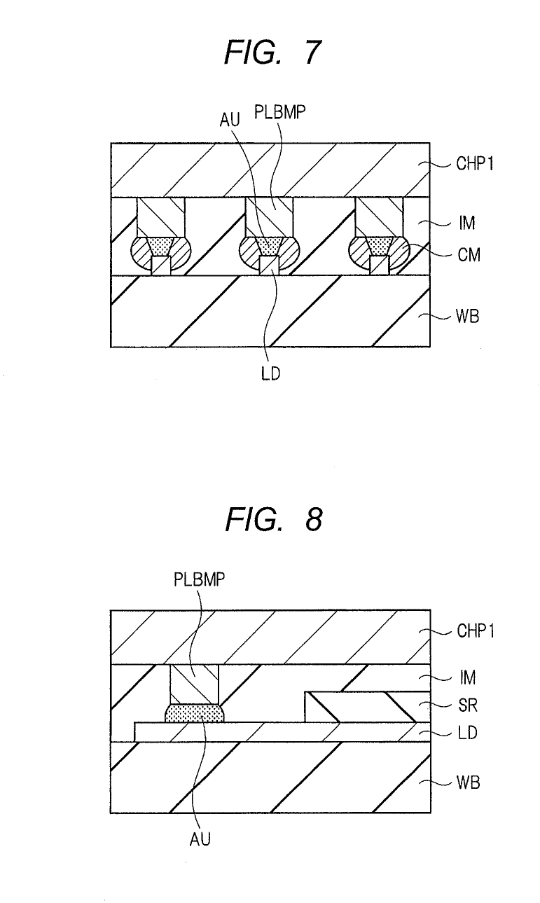

FIG. 7 is a diagram showing a feature of this first embodiment, and is a diagram corresponding to a sectional view cut by the line A-A of FIG. 2. Moreover, FIG. 8 is a diagram showing a feature of this first embodiment, and is a diagram corresponding to a sectional view cut by the line B-B of FIG. 2. The feature in this first embodiment exists, for example, as shown in FIG. 7, in a point that in the conductive material CM that electrically couples the Cu pillar electrode PLBMP and the lead LD, the alloy part AU comprised of an alloy of tin and copper is formed inside this conductive material CM. At this time, the alloy part AU contacts both the Cu pillar electrode PLBMP and the lead LD, and the Cu pillar electrode PLBMP and the lead LD are bound through the alloy part AU. Similarly, also in FIG. 8, it is found that the Cu pillar electrode PLBMP and the lead LD are electrically coupled to each other by the alloy part AU. Thereby, according to this first embodiment, the stable electrical coupling between the Cu pillar electrode PLBMP and the lead LD can be obtained, which makes it possible to improve the electric coupling reliability.

Below, this reason will be explained. The conductive material CM is comprised of the solder containing tin, for example, and the alloy of tin and copper has a property that its melting point is higher than that of tin containing no copper. That is, as shown in FIG. 7, in this first embodiment, the alloy part AU comprised of the alloy of tin and copper is formed at least in a part of the conductive material CM, and a melting point of this alloy part AU becomes higher than a melting point of a portion of the conductive material CM other than the alloy part AU. This means that even when the portion of the conductive material CM other than the alloy part AU is remelted by a heat treatment (solder reflow) carried out in a subsequent process, for example, the alloy part AU is not remelted. As a result, in the alloy part AU, there occurs neither a phenomenon in which the liquid creeps up the side face of the Cu pillar electrode PLBMP nor a phenomenon in which the remelted liquid gets wet and spreads over the surface of the lead LD both of which result from the remelting. For this reason, it is possible to improve the electric coupling reliability between the Cu pillar electrode PLBMP and the lead LD without the heat treatment that is performed in the subsequent process, decreasing the quantity of the alloy part AU for coupling the Cu pillar electrode PLBMP and the lead LD. Especially, as shown in FIG. 7, by forming the alloy part AU so that the alloy part AU may contact both the Cu pillar electrode PLBMP, and the lead LD and so that the Cu pillar electrode PLBMP and the lead LD may be bound through the alloy part AU, it is possible to secure the electric coupling between the Cu pillar electrode PLBMP and the lead LD with the alloy part AU that is not remelted.

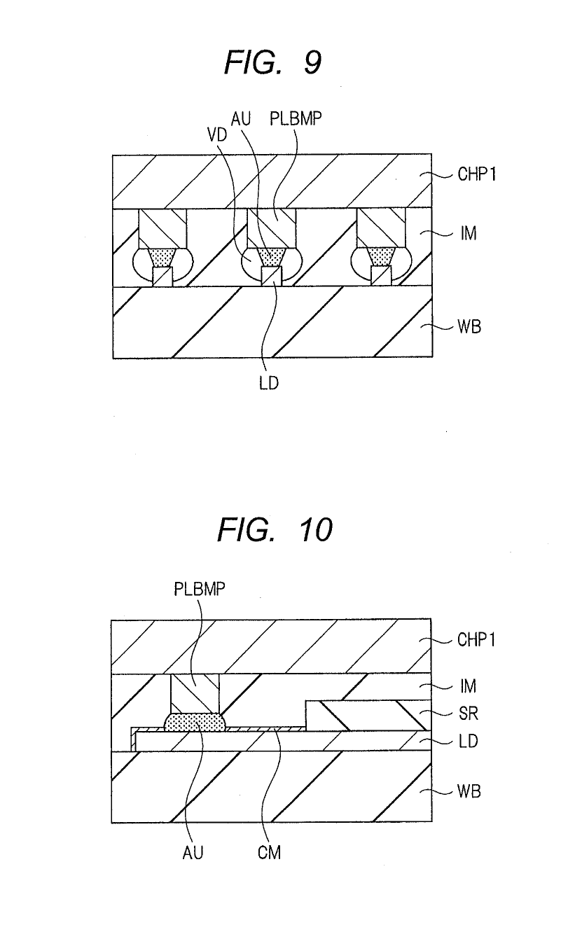

Furthermore, it will be explained concretely. FIG. 9 is a schematic diagram showing a state where a heat treatment is applied after the configuration shown in FIG. 7 is formed; FIG. 10 is a schematic diagram showing a state where a heat treatment is applied after the configuration shown in FIG. 8 is formed.

As are shown in FIG. 9, it is found that the void occurs by the heat treatment causing the portion of the conductive material CM other than the alloy part AU to remelt and, for example, by the remelted liquid flowing into other regions represented by the surface of the lead LD as shown in FIG. 10. However, in this first embodiment, the alloy part AU is formed in a part of the conductive material CM, and this alloy part AU is not remelted because the melting point of this alloy part AU is higher than a temperature of the heat treatment. For this reason, as shown in FIG. 9, even if the conductive material CM other than the alloy part AU flows out, the electric coupling between the Cu pillar electrode PLBMP and the lead LD will be secured by the alloy part AU that will not be remelted. From this, according to this first embodiment, even in the case where a heat treatment is performed after the electric coupling between the Cu pillar electrode PLBMP and the lead LD is established through the conductive material CM, it is possible to improve the electric coupling reliability between the Cu pillar electrode PLBMP and the lead LD.

### <Mode of Alloy Part>

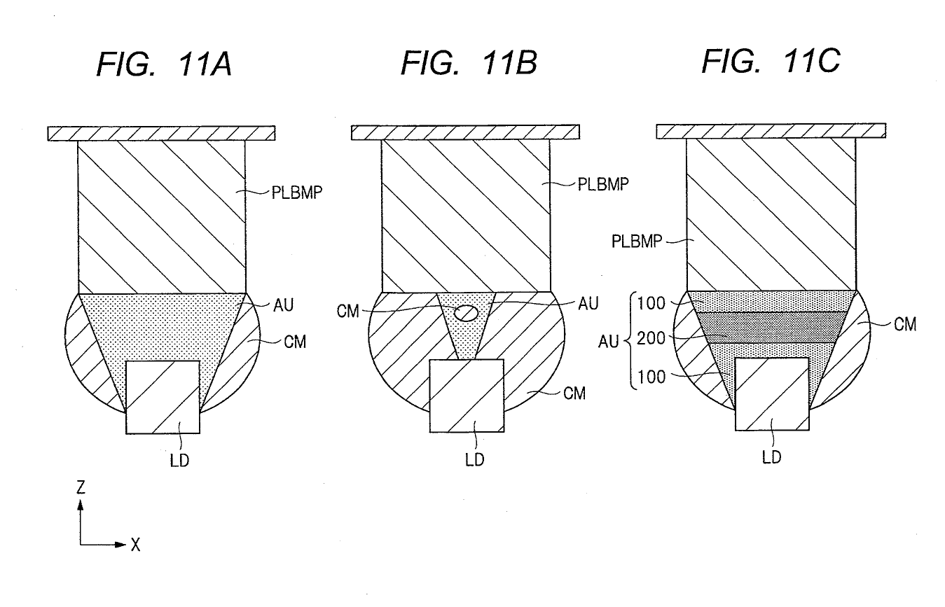

Next, a mode of the alloy part AU will be explained. FIG. 11 is a schematic diagram showing one example of a mode of the alloy part AU in this first embodiment. The alloy part AU in this first embodiment can take a mode shown in FIG. 11A, for example. FIG. 11A is a schematic diagram showing one mode of the alloy part AU in this first embodiment. As shown in FIG. 11A, the alloy part AU in this first embodiment may be comprised of a single alloy phase on the assumption that the alloy part AU is formed so that it may contact both the Cu pillar electrode PLBMP and the lead LD and so that the Cu pillar electrode PLBMP and the lead LD may be bound through the alloy part AU.

Moreover, the alloy part AU in this first embodiment can also take a mode shown in FIG. 11B, for example. FIG. 11B is a schematic diagram showing one mode of the alloy part AU in this first embodiment. As shown in FIG. 11B, in the alloy part AU in this first embodiment, based on the premise that the alloy part AU is formed so that it may contact both the Cu pillar electrode PLBMP and the lead LD and so that the Cu pillar electrode PLBMP and the lead LD may be bound through the alloy part AU, a portion other than the alloy part AU may be formed in island shapes inside the alloy part AU. This is because although in this case, the portion other than the alloy part AU formed in island shapes may be remelted by a heat treatment, this portion does not flow into other regions because it is surrounded by the alloy part AU.

Furthermore, the alloy part AU in this first embodiment can also take a mode shown in FIG. 11C, for example. FIG. 11C is a schematic diagram showing one mode of the alloy part AU in this first embodiment. As shown in FIG. 11C, the alloy part AU in this first embodiment may be comprised of multiple different alloy phases on the assumption that the alloy part AU is formed so that it may contact both the Cu pillar electrode PLBMP and the lead LD and so that the Cu pillar electrode PLBMP and the lead LD are bound through the alloy part AU. For example, as shown in FIG. 11C, the alloy part AU can be configured so as to contain an alloy phase 100 comprised of Cu₃Sn and an alloy phase 200 comprised of Cu₆Sn₅.

Thus, what is necessary for the alloy part AU in this first embodiment to be is just to be formed so that it may contain the alloy of tin and copper and may contact both the Cu pillar electrode PLBMP and the lead LD and so that the Cu pillar electrode PLBMP and the lead LD may be bound through the alloy part AU, and an internal structure of the alloy part AU can take various modes as shown, for example, in FIG. 11A to FIG. 11C. That is, the technical idea in this, first embodiment has the characteristic point that the alloy part AU is formed so that the alloy part AU may contain the alloy of tin and copper and may contact both the Cu pillar electrode PLBMP and the lead LD and so that the Cu pillar electrode PLBMP and the lead LD may be bound through the alloy part AU. Therefore, if the alloy part AU has this characteristic point, regardless of the internal structure of the alloy part AU, it is possible to acquire an effect that electric coupling stability of the Cu pillar electrode PLBMP and the lead LD can be secured and reliability can be improved. In other words, the technical idea in this first embodiment is an idea of forming the alloy part AU that will not be remelted even by a heat treatment represented by the solder reflow in the inside of the conductive material CM, and this idea is embodied by various configurations each of which forms the alloy part AU so that the alloy part AU may have the alloy of tin and copper and may contact both the Cu pillar electrode PLBMP and the lead LD and so that the Cu pillar electrode PLBMP and the lead LD may be bound through the alloy part AU.

Incidentally, it is desirable that a volume ratio of a volume of the alloy part AU to a whole volume of the conductive material CM be as large as possible. This is because the more the volume of the alloy part AU that does not have a possibility of flowing out by the remelting increases, the firmer the electric coupling between the Cu pillar electrode PLBMP and the lead LD becomes, which enables the reliability of the semiconductor device to be improved. For example, from the viewpoint of sufficiently improving the electric coupling reliability between the Cu pillar electrode PLBMP and the lead LD, it is desirable that the volume ratio of the volume of the alloy part AU to the whole volume of the conductive material CM be more than or equal to 50%.

<Configuration Mode (x-Direction Size) of Coupling Part>

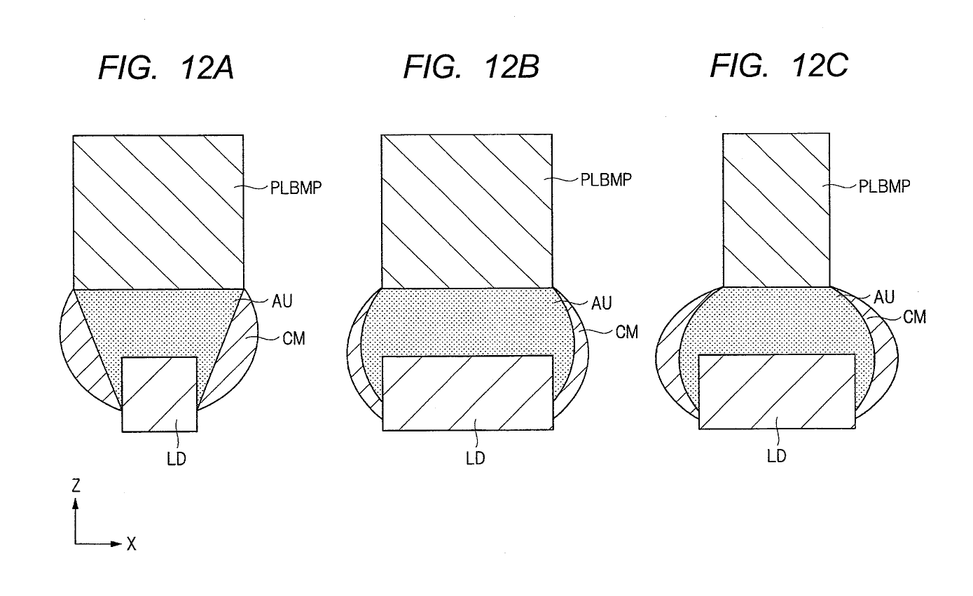

Next, a configuration mode (x-direction size) of a coupling part for coupling the Cu pillar electrode PLBMP and the lead LD with the conductive material CM containing the alloy part AU will be explained. FIG. 12 is a schematic diagram showing one example of a configuration mode of the coupling part. The coupling part in this first embodiment can take a mode shown in FIG. 12A, for example. FIG. 12A is a schematic diagram showing the one mode of the coupling part in this first embodiment. As shown in FIG. 12A, in the coupling part in this first embodiment, an x-direction length of the Cu pillar electrode PLBMP is made longer than an x-direction length of the lead LD. Even in such a configuration of the coupling part, the alloy part AU can be formed so that the alloy part AU may, contact both the Cu pillar electrode PLBMP and the lead LD and so that the Cu pillar electrode PLBMP and the lead LD may be bound through the alloy part AU.

Moreover, the coupling part in this first embodiment can also take a mode shown in FIG. 12B, for example. FIG. 12B is a schematic diagram showing the one mode of the coupling part in this first embodiment. As shown in FIG. 12B, in the coupling part in this first embodiment, the x-direction length of the Cu pillar electrode PLBMP and the x-direction length of the lead LD are made equal. Also in such a configuration of the coupling part, the alloy part AU can be formed so that the alloy part AU may contact both the Cu pillar electrode PLBMP, and the lead LD and so that the Cu pillar electrode PLBMP and the lead LD may be bound through the alloy part AU.

Furthermore, the coupling part in this first embodiment can also take a mode shown in FIG. 12C, for example. FIG. 12C is a schematic diagram showing the one mode of the coupling part in this first embodiment. As shown in FIG. 12C, in the coupling part in this first embodiment, the x-direction length of the Cu pillar electrode PLBMP is made shorter than the x-direction length of the lead LD. Even in such a configuration of the coupling part, the alloy part AU can be formed so that it may contact both the Cu pillar electrode PLBMP and the lead LD and so that the Cu pillar electrode PLBMP and the lead LD may be bound through the alloy part AU.

<Configuration Mode (z-Direction Size) of Coupling Part>

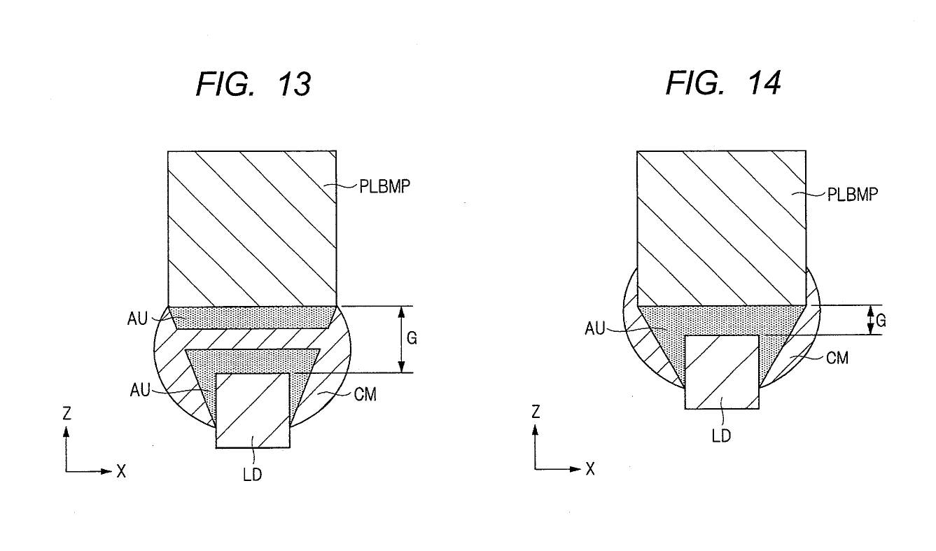

Next, the configuration mode (z-direction size) of the coupling part for coupling the Cu pillar electrode PLBMP and the lead LD with the conductive material CM containing the alloy part AU will be explained. FIG. 13 is a schematic diagram showing one example of the configuration mode of the coupling part. If a z-direction gap G between the Cu pillar electrode PLBMP and the lead LD is too large as shown in FIG. 13, it will become difficult to form the alloy part AU that couples to both the Cu pillar electrode PLBMP and the lead LD. This is because, as will be explained in a manufacturing process that will be described later, the alloy part AU is formed by the following: an alloying heat treatment makes copper contained in the Cu pillar electrode PLBMP diffuse into the conductive material CM; copper contained in the lead LD is made to diffuse into the conductive material CM; and an alloy reaction of the copper that has been diffused to the conductive material CM and tin contained in the conductive material CM occurs. Therefore, as shown in FIG. 13, when the z-direction gap G becomes large, copper does not diffuse into the inside of the conductive material CM, and as a result, there is a possibility that the alloy part AU that contacts the Cu pillar electrode PLBMP and the alloy part AU that contacts the lead LD may be separated. In this case, it becomes impossible to form the alloy part AU so that the alloy part AU may contact both the Cu pillar electrode PLBMP and the lead LD and so that the Cu pillar electrode PLBMP and the lead LD may be bound through the alloy part AU. As a result, there is a possibility that a portion other than the alloy part held by upper and lower alloy parts AU may flow out by the remelting, which may cause occurrence of coupling failure of the Cu pillar electrode PLBMP and the lead LD.

Thereupon, it is desirable to set the z-direction gap G between the Cu pillar electrode PLBMP and the lead LD to be in a range of specified values in this first embodiment from the viewpoint of improving the electric coupling reliability between the Cu pillar electrode PLBMP and the lead LD. FIG. 14 is a schematic diagram showing one example of the configuration mode of the coupling part. As shown in FIG. 14, it is found that when the z-direction gap G between the Cu pillar electrode PLBMP and the lead LD is in a range of appropriate values, the alloy part AU that couples to both the Cu pillar electrode PLBMP and the lead LD can be formed. That is, as shown in FIG. 14, when the z-direction gap G exists in a range of appropriate values, the alloy part AU is formed so that it may contain the alloy of tin and copper and may contact both the Cu pillar electrode PLBMP and the lead LD and so that the Cu pillar electrode, PLBMP and the lead LD may be bound through the alloy part AU. By this, according to this first embodiment, it is possible to improve the electric coupling reliability between the Cu pillar electrode PLBMP and the lead LD even in the case where a heat treatment is performed after the electric coupling between the Cu pillar electrode PLBMP and the lead LD was established through the conductive material CM. From the viewpoint of realizing the technical idea in this first embodiment concretely, for example, it is desirable to set the z-direction gap G between the Cu pillar electrode PLBMP and the lead LD to less than or equal to 15 μm at the maximum, and it is more desirable to set it to not less than 2 μm and not more than 10 μm.

### <Configuration Mode of Cu Pillar Electrode>

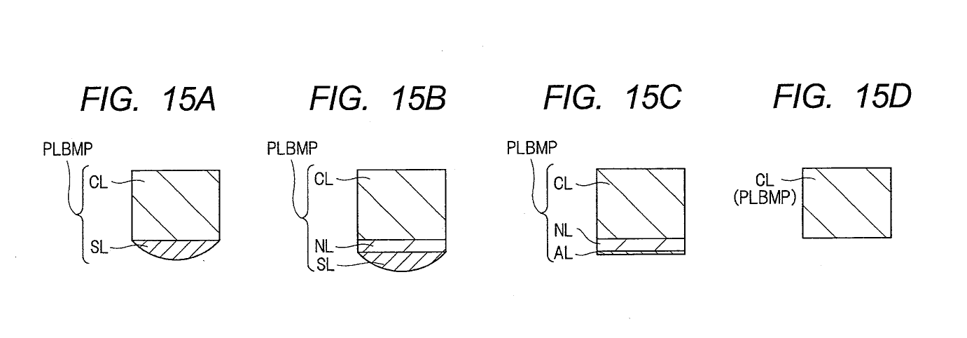

Next, one example of a configuration mode of the Cu pillar electrode PLBMP to which the technical idea in this first embodiment can be applied will be explained. FIGS. 15A and 15D are schematic diagrams showing the one example of the configuration mode of the Cu pillar electrode PLBMP. To be specific, FIG. 15A to FIG. 15D show four configuration modes, respectively.

For example, in FIG. 15A, the Cu pillar electrode PLBMP is comprised of a copper layer CL containing copper as a main component and a solder layer SL that contacts the copper layer CL, and in this first embodiment, the Cu pillar electrode PLBMP shown in, this FIG. 15A can be adopted.

Moreover, in FIG. 15B, the Cu pillar electrode PLBMP is comprised of the copper layer CL containing copper as a main component, a nickel layer NL containing nickel as a main component that contacts the copper layer CL, and the solder layer SL contacting the nickel layer NL, and the Cu pillar electrode PLBMP shown in this FIG. 15B can also be adopted in, this first embodiment.

Furthermore, in FIG. 15C, the Cu pillar electrode PLBMP is comprised of the copper layer CL containing copper as, a main component, the nickel layer NL containing nickel as a main component that contacts the copper layer CL, and a gold layer AL containing gold as a main component that contacts the nickel layer NL, and the Cu pillar electrode PLBMP shown in this FIG. 15C can also be adopted in this first embodiment.

Similarly, in FIG. 15D, the Cu pillar electrode PLBMP is comprised of the copper layer CL containing copper as a main component, and the Cu pillar electrode PLBMP shown in this FIG. 15D can also be adopted in this first embodiment.

Here, the “main component” means a material component that is most contained among constituent materials forming a member (layer) and, for example, the “copper layer containing copper as a main component” means that the copper layer contains the highest portion of copper among its materials. An intention of using the word “main component” in this specification is to express that, for example, although the copper layer is fundamentally comprised of copper, a case where it contains impurities other than copper shall not be excluded. The “main components” in the nickel layer NL and the gold layer AL described above also include the same intention.

### <Configuration Mode of Lead>

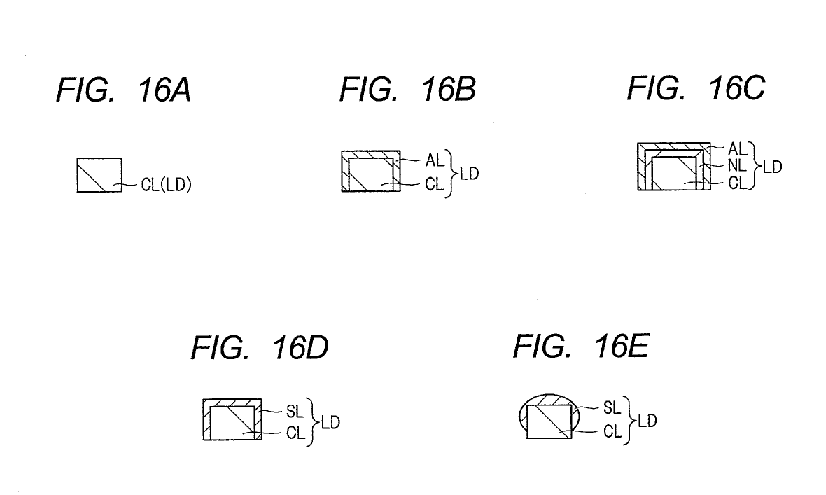

Next, one example of a configuration mode of the lead LD to which the technical idea in this first embodiment is applicable will be explained. FIGS. 16A to 16E are schematic diagrams showing one example of the configuration mode of the lead LD. Specifically, five configuration modes are shown in five diagrams of FIG. 16A to FIG. 16E, respectively.

For example, in FIG. 16A, the lead LD is comprised of the copper layer CL containing copper as a main component, and the lead LD shown in FIG. 16A can be used in this first embodiment.

Moreover, in FIG. 16B, the lead LD is comprised of the copper layer CL containing copper as a main component and the gold layer AL containing gold as a main component that contacts the copper layer CL, and the lead LD shown in this FIG. 15B can also be adopted in this first embodiment.

Furthermore, in FIG. 16C, the lead LD is comprised of the copper layer CL containing copper as a main component, the nickel layer NL containing nickel as a main component that contacts the copper layer CL, and the gold layer AL containing gold as a main component that contacts, the nickel layer NL, and the lead LD shown in this FIG. 16C can also be adopted in this first embodiment.

Moreover, in FIG. 16D, the lead LD is comprised of the copper layer CL containing copper as a main component and the solder layer SL contacting the copper layer CL (electrolysis plating or electroless plating), and the lead LD shown in this FIG. 16D can also be adopted in this first embodiment.

Similarly, in FIG. 16E, the lead LD is comprised of the copper layer CL containing copper as a main component and the solder layer SL contacting the copper layer CL (solder pre-coat), and the lead LD shown in this FIG. 16E can also be adopted in this first embodiment.

### <Combination of Cu Pillar Electrode and Lead>

Although the technical idea in this first embodiment is applicable to the Cu pillar electrode PLBMP of various configuration modes described above and the lead LD of various configuration modes described above, in order to realize the technical idea in this first embodiment, certain restrictions exist in a combination of the Cu pillar electrode PLBMP and the lead LD. Concretely, since the technical idea in this first embodiment is predicated on a fact that the Cu pillar electrode PLBMP and the lead LD are coupled to each other through the solder (conductive material CM), the certain restrictions exist in the combination of the Cu pillar electrode PLBMP and the lead LD from this viewpoint. Below, the combination of the Cu pillar electrode PLBMP and the lead LD will be explained.

First, in the case of using the Cu pillar electrode PLBMP shown in FIG. 15A, since the solder layer SL is formed over the Cu pillar electrode PLBMP, the lead LD of any one of configuration modes of FIG. 16A to FIG. 16E can be used as a corresponding lead LD.

Next, in the case of using the Cu pillar electrode PLBMP shown in FIG. 15B, the solder layer SL is formed over the Cu pillar electrode PLBMP, and the nickel layer NL for suppressing diffusion of copper from the copper layer CL to the solder layer SL is formed. From this configuration, in order to form the alloy part in the solder layer SL, the solder layer SL needs to be formed on the lead LD side. That is, in the case of using the Cu pillar electrode PLBMP shown in FIG. 15B, since the diffusion of copper from the Cu pillar electrode PLBMP side cannot be expected, the solder layer SL needs to be supplied with copper from the lead LD side. For this reason, in the case of using the Cu pillar electrode PLBMP shown in FIG. 15B, the corresponding lead LD is limited to the lead LD of any one of the configuration modes of FIG. 16D and FIG. 16E. Thus, from the viewpoint of forming the alloy part in the solder layer SL (conductive material), it cannot be said that the configuration of providing the nickel layer NL is desirable. However, this nickel layer NL has a function of suppressing the liquid from creeping up the side face of the Cu pillar electrode PLBMP when the solder layer SL (conductive material) is remelted. From this, in the case where the diffusion of copper is sufficiently performed from the lead LD side to the solder layer SL, synergistic effects can be obtained in a point that the alloy part is formed in the inside of the solder layer SL and in a point that creep-up of the liquid to the side face of the Cu pillar electrode PLBMP is suppressed by the nickel layer NL.

Finally, in the case of using the Cu pillar electrodes PLBMP shown in FIG. 15C and FIG. 15D, since the solder layer SL is not formed over the Cu pillar electrode PLBMP, the corresponding lead LD will be limited to the lead LD of any one of the configuration modes of FIG. 16D and FIG. 16E.

### <Manufacturing Method of Semiconductor Device>

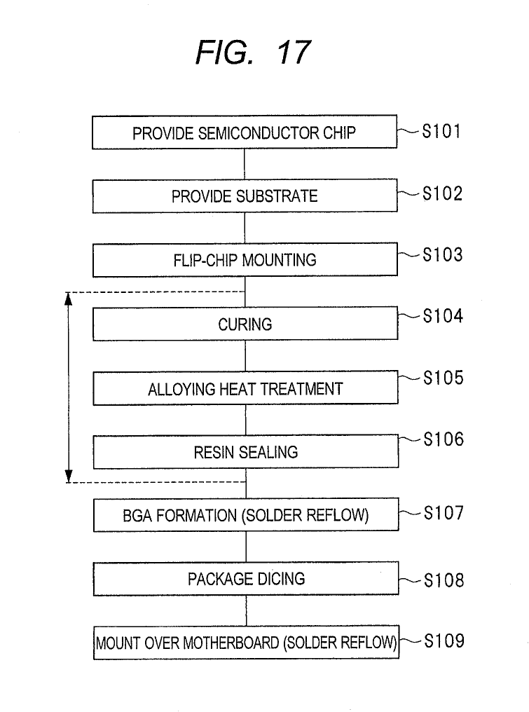

The semiconductor device PAC1 in this first embodiment is formed as described above, and its manufacturing method will be explained referring to, drawings below. FIG. 17 is a flowchart showing a flow of a manufacturing process of the semiconductor device in this first embodiment.

First, a semiconductor chip in which an integrated circuit that uses the semiconductor element and wiring as its constituents is formed in its inside and over whose surface the Cu pillar electrode (projection electrode) containing copper is formed is prepared (S101 of FIG. 17). Moreover, wiring board over whose surface multiple leads containing copper as a main component are formed is also prepared (S102 of FIG. 17).

Next, a semiconductor chip is flip-chip mounted over the wiring board (S103 of FIG. 17). Specifically, the semiconductor chip is mounted over the wiring board so that the Cu pillar electrode formed in the semiconductor chip and the lead formed over the wiring board may be electrically coupled to each other. There are various kinds in this flip-chip mounting, for example, there are four modes that are shown below as typical flip-chip mounting processes and each process will be explained referring to drawings.

### First Example

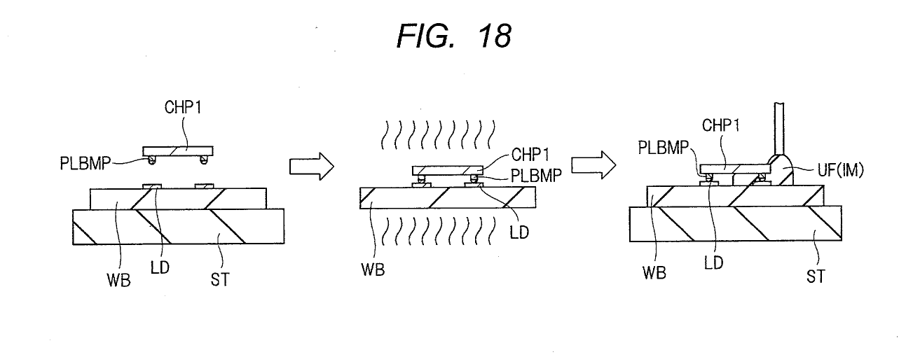

A first example of the flip-chip mounting process will be explained using FIG. 18. As shown in FIG. 18, the wiring board WB whose surface is cleansed by plasma cleaning and over which the lead LD is formed is arranged over a stage ST, and subsequently the semiconductor chip CHP1 is mounted over the wiring board WB. At this time, the semiconductor chip CHP1 is mounted over the wiring board WB so that the Cu pillar electrode PLBMP formed in the semiconductor chip CHP1 may be coupled to the lead LD formed over the wiring board WB.

Next, for example, the wiring board WB over which the semiconductor chip CHP1 is mounted is subjected to a heat treatment (Mass reflow). To be specific, the wiring board WB over which the semiconductor chip CHP1 is mounted is heated, for example, at a temperature of 260° C. (second temperature) higher than a melting point of the solder. Thereby, the Cu pillar electrode PLBMP formed in the semiconductor chip CHP1 and the lead LD formed over the wiring board WB are coupled to each other by the conductive material comprised of the solder.

Next, a gap between the wiring board WB and the semiconductor chip CHP1 is filled with underfill UF (insulating resin material IM). Thus, the flip-chip mounting process of mounting the semiconductor chip CHP1 over the wiring board WB is performed.

### Second Example

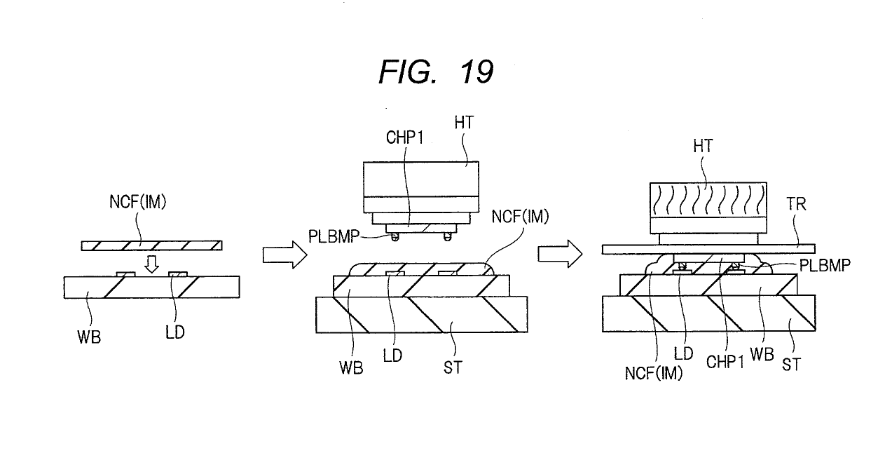

A second example of the flip-chip mounting process will be explained using FIG. 19. As shown in FIG. 19, a pre-application resin film NCF (insulating resin material IM) is arranged over the wiring board WB whose surface is cleansed by plasma cleaning and over which the lead LD is formed. After that, the semiconductor chip CHP1 in which the Cu pillar electrode PLBMP is formed is mounted over the wiring board WB covered with the pre-application resin film NCF. At this time, because of a load by the heater HT holding the semiconductor chip CHP1, the Cu pillar electrode PLBMP formed in the semiconductor chip CHP1 breaks through the pre-application resin film NCF, and contacts directly the lead LD formed over the wiring board WB.

After that, the semiconductor chip CHP1 is heated by the heater HT while the semiconductor chip CHP1 is being pressed by the heater HT through a fluorocarbon resin TR. To be specific, the semiconductor chip CHP1 is heated by the heater HT, for example, at a temperature (second temperature) of 260° C. higher than the melting point of the solder. Thereby, the Cu pillar electrode PLBMP formed in, the semiconductor chip CHP1 and the lead LD formed over the wiring board WB are coupled to each other by the conductive material comprised of the solder. Thus, the flip-chip mounting process of mounting the semiconductor chip CHP1 over the wiring board WB is performed.

### Third Example

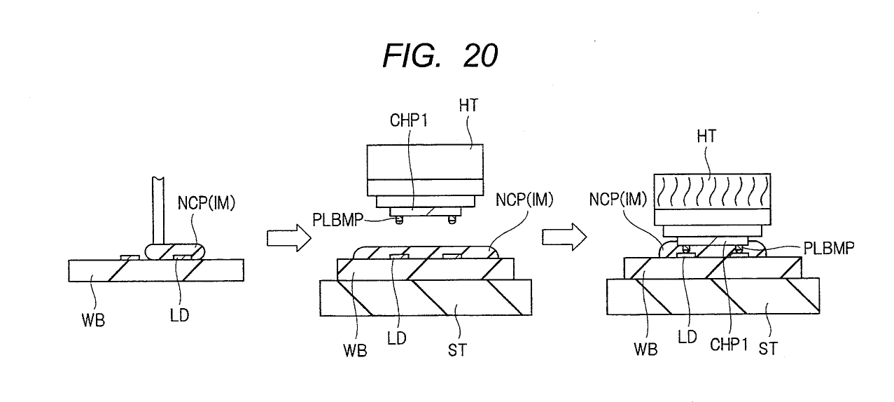

A third example of the flip-chip mounting process will be explained using FIG. 20. As shown in FIG. 20, pre-application resin paste NCP (insulating resin material IM) is formed over the wiring board WB whose surface is cleansed by plasma cleaning and over which the lead LD is formed. After that, the semiconductor chip CHP1 in which the Cu pillar electrode PLBMP is formed is mounted over the wiring board WB covered with the pre-application resin paste NCP. At this time, because of the load by the heater HT holding the semiconductor chip CHP1, the Cu pillar electrode PLBMP formed in the semiconductor chip CHP1 thrusts away the pre-application resin paste NCP, and contacts directly the lead LD formed over the wiring board WB.

After that, the semiconductor chip CHP1 is heated by the heater HT while the semiconductor chip CHP1 is being pressed by the heater HT. To be specific, for example, the semiconductor chip CHP1 is heated by the heater HT, for example, at a temperature (second temperature) of 260° C. higher than the melting point of the solder. Thereby, the Cu pillar electrode PLBMP formed in the semiconductor chip CHP1 and the lead LD formed over the wiring board WB are coupled to each other by the conductive material comprised of the solder. Thus, the flip-chip mounting process of mounting the semiconductor chip CHP1 over the wiring board WB is performed.

### Fourth Example

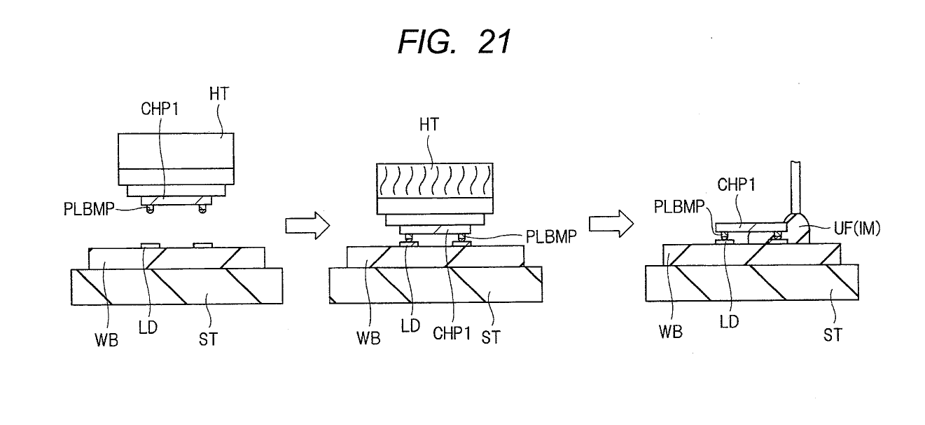

A fourth example of the flip-chip mounting process will be explained using FIG. 21. As shown in FIG. 21, it is the wiring board WB whose surface is cleansed by plasma cleaning, the wiring board WB over which the lead LD is formed is arranged over the stage ST, and subsequently the semiconductor chip CHP1 is mounted over the wiring board WB while the semiconductor chip CHP1 is being held by the heater HT. At this time, the semiconductor chip CHP1 is mounted over the wiring board WB so that the Cu pillar electrode PLBMP formed in the semiconductor chip CHP1 may be coupled to the lead LD formed over the wiring board WB.

Next, the semiconductor chip CHP1 is heated by the heater HT holding the semiconductor chip CHP1. To be specific, the semiconductor chip CHP1 is heated by the heater HT, for example, at a temperature of 260° C. (second temperature) higher than the melting point of the solder. Thereby, the Cu pillar electrode PLBMP formed in the semiconductor chip CHP1 and the lead LD formed over the wiring board WB are coupled to each other by the conductive material comprised of the solder.

Next, the underfill UF (insulating resin material IM) is filled in the gap between the wiring board WB and the semiconductor chip CHP1. Thus, the flip-chip mounting process of mounting the semiconductor chip CHP1 over the wiring board WB is performed.

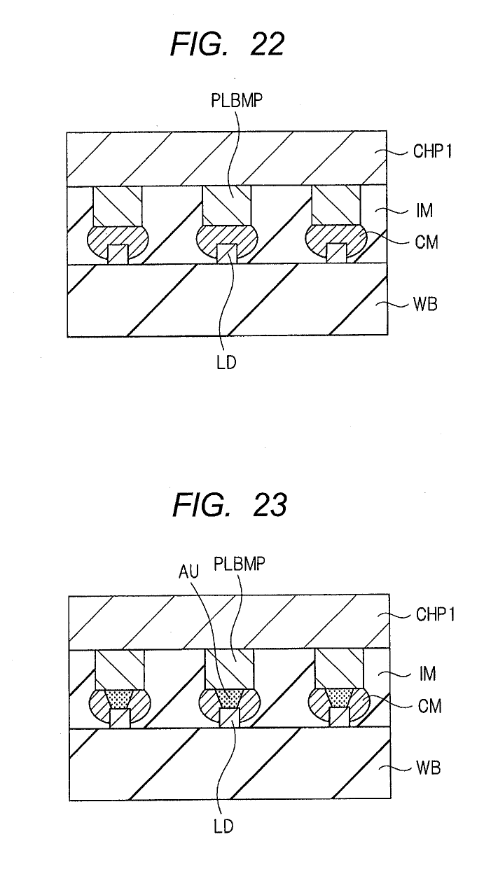

By the flip-chip mounting processes (first example to the fourth example) as the above, the semiconductor chip CHP1 is flip-chip mounted over the wiring board WB. FIG. 22 is an enlarged sectional view showing a condition where the semiconductor chip CHP1 is flip-chip mounted over the wiring board WB. As shown in FIG. 22, the lead LD formed over the wiring board WB and the Cu pillar electrode PLBMP formed in the semiconductor chip CHP1 will be electrically coupled by the conductive material CM containing tin. Then, the gap between the semiconductor chip CHP1 and the wiring board WB is filled with the insulating resin material IM (in the first example and the fourth example, the underfill UF; in the second example, the pre-application resin film NCF; and in the third example, the pre-application resin paste NCP).

Here, since the above-mentioned insulating resin material IM has not hardened completely, a curing process is performed next (S104 of FIG. 17). To be specific, a heat treatment (curing), for example, at a temperature (third temperature) of 170° C. for about one hour is carried out. Thereby, the insulating resin material IM can be hardened completely.

Next, the alloying heat treatment that is a characteristic process of this first embodiment is carried out (S105 of FIG. 17). For example, the conductive material CM is heated at a first temperature that is higher than the normal temperature (room temperature 25° C.) and is lower than a melting point of the conductive material CM. To be specific, a heat treatment process at a temperature of 200° C. (first temperature) for about 12 hours is carried out. Thereby, as shown in FIG. 23, copper diffuses into the conductive material CM from the Cu pillar electrode PLBMP and the lead LD, the copper diffused into the conductive material CM and tin contained in the conductive material CM perform an alloy reaction to form the alloy part AU in the inside of the conductive material CM. In detail, the alloying heat treatment forms the alloy part AU so that it may contain the alloy of tin and copper and may contact both the Cu pillar electrode PLBMP and the lead LD and so that the Cu pillar electrode PLBMP and the lead LD may be bound through the alloy part AU. In this first embodiment, for example, an alloy phase comprised of Cu₃Sn is formed so as to contact the Cu pillar electrode PLBMP and the lead LD, and an alloy phase comprised of Cu₆Sn₅ is formed inside the alloy phase comprised of Cu₃Sn. Melting points of these alloy phases exceed 415° C.

Here, although it is desirable that the first temperature of the alloying heat treatment be as high a temperature as possible considering productivity of forming the alloy part AU, it needs to be a temperature lower than the melting point of the conductive material CM (solder). Incidentally, in this first embodiment, although as a specific condition of the alloying heat treatment, the condition of a temperature of 200° C. (first temperature) for about 12 hours is given as an example, this is only one example, and the heating temperature and the heating time may change depending on a kind of the solder that forms the conductive material CM.

Moreover, it is desirable that the alloying heat treatment be carried out, for example, in a nitrogen atmosphere, an inert gas atmosphere, or an atmosphere of high degree of vacuum. This is because the alloying heat treatment may cause, for example, the surface of the lead LD formed over the wiring board WB to oxidize.

After carrying out the alloying heat treatment as described above, as shown in FIG. 1, the sealing body MR comprised of a resin is formed so as to cover the semiconductor chip CHP1 (S106 of FIG. 17), for, example. In this resin sealing process, the resin is hardened, for example, by forming the resin so that it may cover the semiconductor chip CHP1 and subsequently carrying out a heat treatment at a temperature of 175° C. for about one hour.

After that, as shown in FIG. 1, the solder balls SB are mounted over the rear surface of the wiring board WB, and subsequently solder reflow at about 260° C. is performed (S107 of FIG. 17). At this time, the conductive material that electrically couples the Cu pillar electrode PLBMP and the lead will be remelted. However, in this first embodiment, since the alloy part having a high melting point that does not allow it to remelt is formed in the inside of the conductive material, it is possible to improve the electric coupling reliability between the Cu pillar electrode PLBMP and the lead.

Next, the multiple semiconductor devices PAC1 (refer to FIG. 1) can be obtained by performing package dicing of the wiring board WB (S108 of FIG. 17). Thus, the semiconductor device PAC1 in this first embodiment can be manufactured.

After the manufactured semiconductor device PAC1 is delivered to a customer, it is mounted over the motherboard (S109 of FIG. 17). Also at this time, the solder reflow at about 260° C. is performed in a process of coupling the motherboard and the semiconductor device PAC1. At this time, although the conductive material that electrically couples the Cu pillar electrode and the lead will be remelted, since the alloy part having the high melting point that does not allow it to remelt is formed in the inside of the conductive material, it is possible to improve the electric coupling reliability between the Cu pillar electrode and the lead.

### Effect of First Embodiment

According to this first embodiment, the alloying heat treatment is provided in a process before the heat treatment process (solder reflow) having a possibility that the conductive material CM may be remelted, and in the conductive material CM that electrically couples the Cu pillar electrode PLBMP and the lead LD, the alloying heat treatment forms an alloy part AU comprised of the alloy of tin and copper inside this conductive material CM. In particular, in this first embodiment, this alloy part AU is formed so that it may contact both the Cu pillar electrode PLBMP and the lead LD and so that the Cu pillar electrode PLBMP and the lead LD may be bound through the alloy part AU. Then, since the melting point of this alloy part AU is higher than, for example, a temperature of the heat treatment (solder reflow) shown by S107 and S109 in FIG. 17, it will not be remelted.

Therefore, even if the conductive material CM other than the alloy part AU flows out, the electric coupling between the Cu pillar electrode PLBMP and the lead LD will be secured by the alloy part AU that will not be remelted. From this, according to this first embodiment, even in the case where the heat treatment (solder reflow) is carried out after the electric coupling between the Cu pillar electrode PLBMP and the lead LD is performed through the conductive material CM, it is possible to improve the electric coupling reliability between the Cu pillar electrode PLBMP and the lead LD.

### <Modification>

Next, a modification of this first embodiment will be explained. In this first embodiment, as shown in FIG. 17, the alloying heat treatment is carried out after the curing process and before the resin sealing process. However, the technical idea in this first embodiment resides in a point, as a fundamental idea, that after the Cu pillar electrode PLBMP and the lead LD are coupled through the conductive material CM by the flip-chip mounting process, the alloying heat treatment is carried out, for example, so that the conductive material CM may not be remelted by a BGA formation process (solder reflow) and a mounting process (solder reflow) over the motherboard. Therefore, if this fundamental idea is taken into consideration, the alloying heat treatment that is characteristic of this first embodiment can be carried out at any point of time after the flip-chip mounting process and before the BGA formation process.

For example, the curing process and the alloying heat treatment can also be carried out together. In this case, since reduction in the number of processes can be achieved, simplification of the manufacturing process of the semiconductor device can be achieved. However, a temperature applied by the curing process is about 170° C., and a temperature applied by the alloying heat treatment is about 200° C. Therefore, when combining the curing process and the alloying heat treatment, the insulating resin material IM will be heated more rapidly than in the usual curing process. The curing process is a heat treatment for completely hardening the insulating resin material IM and, for example, when heating the insulating resin material IM rapidly, possibility increases that the rapid heating may cause the polyimide resin formed in the semiconductor chip CHP1 and constituent materials of the wiring board WB to emit outgas. Then, there is a possibility that a void may occur between the semiconductor chip CHP1 and the wiring board WB by this outgas being taken into the insulating resin material IM that is in a semidry state where the material has not hardened completely, and it is necessary to take measures from the viewpoint of improving the reliability of the semiconductor device. As one example of the measure, for example, when combining the curing process and the alloying heat treatment, a technique by which the insulating resin material IM is at first heated at temperature of about 170° C. corresponding to the curing and subsequently the temperature is increased to about 200° C. gradually, not being heated from the first to about 200° C., is conceivable. Therefore, for example, by taking the measure described above, it is possible to simplify the manufacturing process of the semiconductor device by carrying out the curing process and the alloying heat treatment together, without causing reliability deterioration of the semiconductor device.

Moreover, since the alloying heat treatment in this first embodiment needs to be carried out, at least, in a process before the BGA formation process, it can also be carried out after the resin sealing process. However, in this case, the sealing body MR comprised of the resin may suffer damage from heat applied by the alloying heat treatment. Although the alloying heat treatment in this first embodiment can be carried out at any point of time after the flip-chip mounting process and before the BGA formation process, it is desirable that the alloying heat treatment be carried out in as early a stage as possible from the viewpoint of lessening an influence that is given to other constituents of the semiconductor device.

### Second Embodiment

In the first embodiment, although the semiconductor device PAC1 in which the single body semiconductor chip CHP1 was mounted over the wiring board WB as shown in FIG. 1, for example, was taken as an example and explained; in this second embodiment, semiconductor device in which multiple semiconductor chips are arranged in a stacked state over the wiring board will be taken as an example and explained.

### <Configuration of Semiconductor Device>

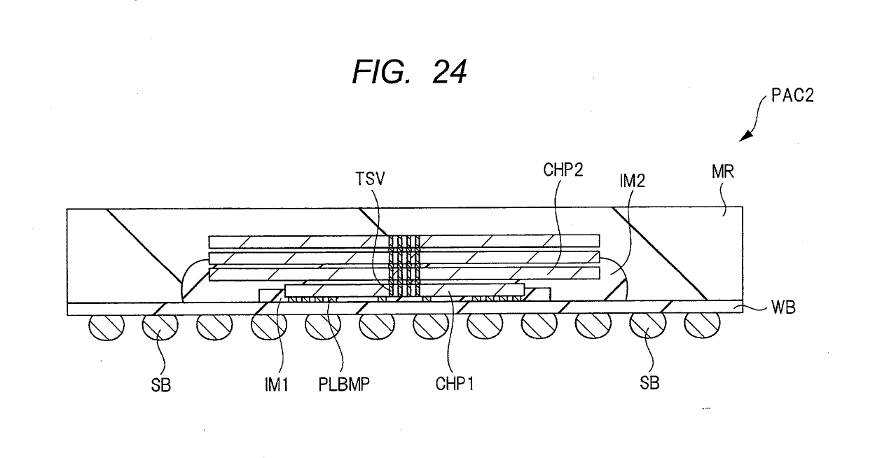

FIG. 24 is a sectional view showing a schematic configuration of a semiconductor device PAC2 in this second embodiment. As shown in FIG. 24, the semiconductor device PAC2 in this second embodiment has the wiring board WB, for example, in which the multilayer interconnection is formed in its inside; and the semiconductor chip CHP1 is mounted over an upper surface of this wiring board WB. Then, a semiconductor chip CHP2 is arranged above the semiconductor chip CHP1 so as to be stacked and arranged to this semiconductor chip CHP1.

By establishing electrical coupling between the lead (electrode) formed over the upper surface of the wiring board WB (not illustrated in FIG. 24) and the Cu pillar electrode (projection electrode) PLBMP formed in the semiconductor chip CHP1, the semiconductor chip CHP1 and the wiring board WB will be electrically coupled to each other. Here, the Cu pillar electrode PLBMP formed in the semiconductor chip CHP1 is comprised of, for example, a material containing copper and the lead formed over the wiring board WB is also comprised of a material containing copper.

Moreover, a through silicon via TSV that penetrates the semiconductor chip CHP1 is formed in the semiconductor chip CHP1, and a coupling part is formed between the semiconductor chip CHP1 and the semiconductor chip CHP2 so as to couple with this through silicon via TSV. Therefore, the semiconductor chip CHP1 and the semiconductor chip CHP2 that are arranged in a stacked state will be in a state where they are electrically coupled to each other through the coupling part and the through silicon via TSV. For example, a plane size of the semiconductor chip CHP1 arranged in a lower layer is made smaller than that of the semiconductor chip CHP2 arranged in an upper layer. Then, while a logic circuit is formed in the semiconductor chip CHP1, for example, a memory circuit is formed in the semiconductor chip CHP2, for example. On the other hand, multiple solder balls SB that are to be electrically coupled with the multilayer interconnection formed in the inside of the wiring board WB are provided over the undersurface of the wiring board WB. Furthermore, as shown in FIG. 24, the gap between the semiconductor chip CHP1 and the wiring board WB is filled with an insulating resin material IM1, and a gap between the semiconductor chip CHP1 and the semiconductor chip CHP2 is, filled with an insulating resin material IM2. Moreover, the sealing body MR comprised of, for example, a resin is provided so as to cover the semiconductor chip CHP2 over the wiring board WB. The semiconductor device PAC2 thus configured in this second embodiment also has the characteristic point explained in the first embodiment. That is, also in the semiconductor device PAC2 in this second embodiment, in the conductive material that electrically couples the Cu pillar electrode and, the lead, an alloy part comprised of the alloy of tin and copper is formed inside this conductive material. Then, this alloy part contacts both the Cu pillar electrode PLBMP and the lead, and the Cu pillar electrode PLBMP and the lead are bound through the alloy part. Thereby, like the first embodiment, also in this second embodiment, it is possible to improve the electric coupling reliability between the Cu pillar electrode PLBMP and the lead.

### <Manufacturing Method of Semiconductor Device>

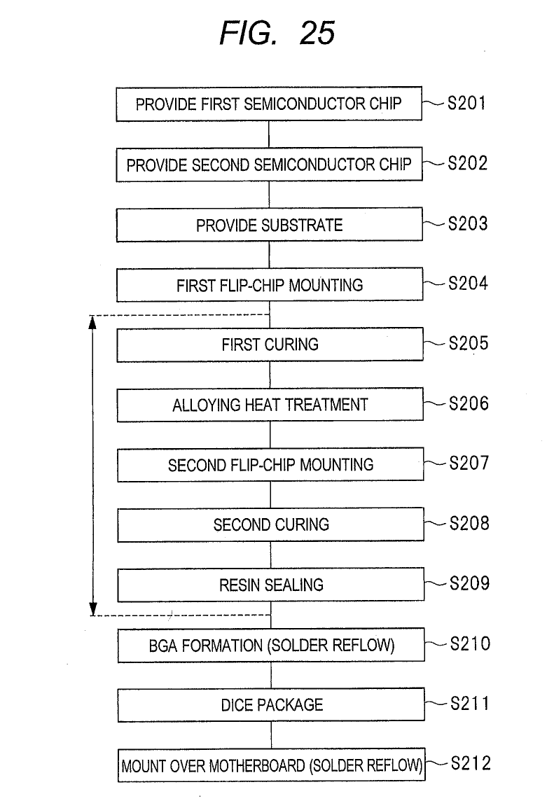

The semiconductor device PAC2 in this second embodiment is configured as described above, and its manufacturing method will be explained referring to drawings below. FIG. 25 is a flowchart showing the manufacturing process of the semiconductor device in this second embodiment.

First, a first semiconductor chip inside which a logic circuit that uses the semiconductor element and wiring as its constituents is formed and over whose surface the Cu pillar electrode (projection electrode) containing copper is formed is prepared (S201 of FIG. 25), and a second semiconductor chip inside which a memory circuit that uses the semiconductor element and wiring as its constituents is formed and over whose surface the Cu pillar electrode (projection electrode) containing copper is formed is prepared (S202 of FIG. 25), Moreover, a wiring board over whose surface multiple leads containing copper as a main component are formed is also prepared (S203 of FIG. 25).

Next, the first semiconductor chip is first flip-chip mounted over the wiring board (S204 of FIG. 25). To be specific, the first semiconductor chip is Mounted over the wiring board so that the Cu pillar electrode formed in the first semiconductor chip and the lead formed over the wiring, board may be electrically coupled to each other. This first flip-chip mounting can be performed in any one of processes of the first example to the fourth example that were explained in the first embodiment, for example.

The first flip-chip mounting process described above will establish the electric coupling between the lead formed over the wiring board and the Cu pillar electrode formed in the first semiconductor chip with the conductive material containing tin. Then, an insulating resin material (an underfill, a pre-application resin film, or pre-application resin paste) is filled in gap between the first semiconductor chip and the wiring board.

Here, since the above-mentioned insulating resin material has not hardened completely, next, the first curing process is performed (S205 of FIG. 25). To be specific, a heat treatment (curing), for example, at a temperature of 170° C. (third temperature) for about one hour is carried out. Thereby, the insulating resin material can be hardened completely.

Next, the alloying heat treatment that is a characteristic process of this, second embodiment is carried out (S206 of FIG. 25). For example, the conductive material is heated at the first temperature that is higher than the normal temperature (room temperature 25° C.) and is lower than the melting point of the conductive material (solder). To be specific, a heat treatment process at a temperature of 200° C. (first temperature) for about 12 hours is carried out. Thereby, copper diffuses into the conductive material from the Cu pillar electrode and the lead, copper that diffused into the conductive material and tin contained in the conductive material make an alloy reaction, and an alloy part is formed in the inside of the conductive material. To be specific, the alloying heat treatment forms the alloy part so that the alloy part may contain the alloy of tin and copper, and contact both the Cu pillar electrode and the lead and so that the Cu pillar electrode and the lead may be bound through the alloy part. In this second embodiment, for example, an alloy phase comprised of Cu₃Sn is formed so as to contact the Cu pillar electrode and the lead, and an alloy phase comprised of Cu₆Sn₅ is formed inside the alloy phase comprised of Cu₃Sn. The melting points of these alloy phases exceed 415° C.

Here, it is desirable that the first temperature of the alloying heat treatment be as high a temperature as possible considering the productivity of forming the alloy part, but it must be a lower temperature than the melting point of the conductive material (solder). Incidentally, in this second embodiment, although as a specific condition of the alloying heat treatment, a condition of a temperature of 200° C. (first temperature) for about 12 hours is given for an example, this is only one example, and heating temperature and heating time may change depending on a kind of solder that forms the conductive material. Moreover, it is desirable to carry out the alloying heat treatment, for example, in a nitrogen atmosphere, an inert gas atmosphere, or an atmosphere with high degree of vacuum. This is because there is a possibility that the alloying heat treatment may cause the wiring board to deteriorate (oxidization of land, etc.), for example, which may inhibit mounting of the BGA balls (solder balls).

Next, the second semiconductor chip is second flip-chip mounted over the first semiconductor chip (S207 of FIG. 25). To be specific, the second semiconductor chip is mounted over the first semiconductor chip so that the Cu pillar electrode formed in the second semiconductor chip and the through silicon via formed in the first semiconductor chip may be electrically coupled to each other. There are various kinds of this second flip-chip mounting. For example, as typical flip-chip mounting processes, there are two modes shown below. Each process will be explained referring to drawings.

### First Example

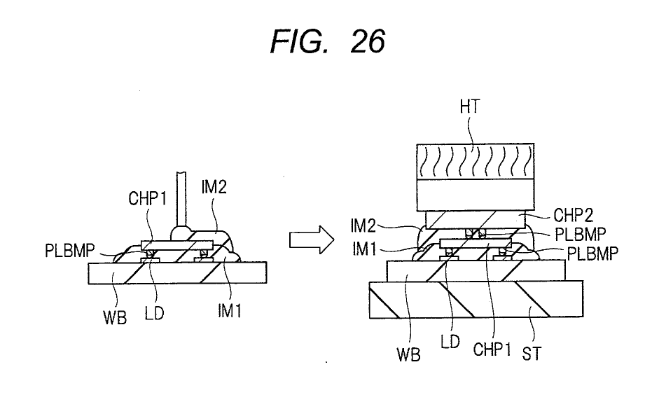

A first example of a second flip-chip mounting process will be explained using FIG. 26. As shown in FIG. 26, for example, the surface of the wiring board WB is cleansed by plasma cleaning, and subsequently, pre-application resin paste (insulating resin material IM2) is formed over the semiconductor chip CHP1 (first semiconductor chip) in which the through silicon via is formed. After that, the semiconductor chip CHP2 (second semiconductor chip) in which the Cu pillar electrode PLBMP is formed is mounted over the semiconductor chip CHP1 covered with the pre-application resin paste. At this time, because of a load by the heater HT holding the semiconductor chip CHP2, the Cu pillar electrode PLBMP formed in the semiconductor chip CHP2 thrusts away the pre-application resin paste NCP, and contacts directly the through silicon via formed in the semiconductor chip CHP1.

After that, the semiconductor chip CHP2 is heated by the heater HT while the semiconductor chip CHP2 is being pressed by the heater HT. To be specific, the semiconductor chip CHP2 is heated by the heater HT, for example, at a temperature of 260° C. (second temperature) higher than the melting point of the solder. Thereby, the Cu pillar electrode PLBMP formed in the semiconductor chip CHP2 and the through silicon via formed in the semiconductor chip CHP1 are coupled to each other by the conductive material comprised of the solder. Thus, the second flip-chip mounting process of mounting the semiconductor chip CHP2 over the semiconductor chip CHP1 is performed.

### Second Example

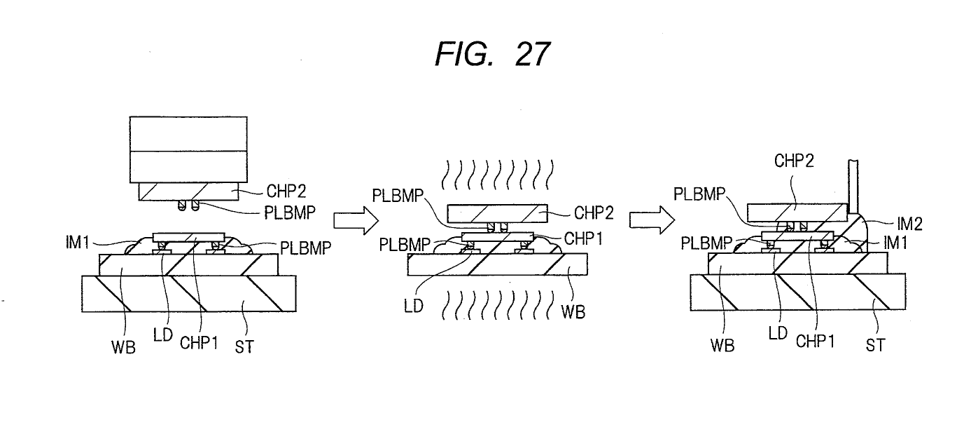

A second example of the second flip-chip mounting process will be explained using FIG. 27. As shown in FIG. 27, for example, the surface of the wiring board WB is cleansed by plasma cleaning, and subsequently the semiconductor chip CHP2 (second semiconductor chip) is mounted over the semiconductor chip CHP1 (first semiconductor chip). At this time, the semiconductor chip CHP2 is mounted over the semiconductor chip CHP1 so that the Cu pillar electrode PLBMP formed in the semiconductor chip CHP2 may be coupled to the through silicon via formed in the semiconductor chip CHP1.

Next, for example, a heat treatment is carried out on the wiring board WB in which the semiconductor chip CHP1 and the semiconductor chip CHP2 are arranged in a stacked state (Mass reflow). To be specific, the wiring board WB in which the semiconductor chip CHP1 and the semiconductor chip CHP2 are arranged in a stacked state is heated, for example, at temperature of 260° C. (second temperature) higher than the melting point of the solder. Thereby, the Cu pillar electrode PLBMP formed in the semiconductor chip CHP2 and the through silicon via formed in the semiconductor chip CHP1 are coupled to each other by the conductive material comprised of the solder.

Next, the gap between the semiconductor chip CHP1 and the semiconductor chip CHP2 is filled with an underfill (insulating resin material IM2). Thus, the second flip-chip mounting process of mounting the semiconductor chip CHP2 over the semiconductor chip CHP1 is performed.

Here, since the above-mentioned insulating resin material IM2 has not hardened completely, next, a second curing process is performed (S208 of FIG. 25). To be specific, a heat treatment (curing), for example, at the temperature of 170° C. (third temperature) for about one hour is carried out. Thereby, the insulating resin material IM2 can be hardened completely.

After that, for example, as shown in FIG. 24, the sealing body MR comprised of the resin is formed so as to cover the semiconductor chip CHP2 (S209 of FIG. 25). In this resin sealing process, the resin is hardened, for example, by forming the resin so that it may cover the semiconductor chip CHP2 and subsequently carrying out a heat treatment at a temperature of 175° C. for about one hour.

Next, as shown in FIG. 24, the solder balls SB are mounted over the rear surface of the wiring board WB, and subsequently the solder reflow at about 260° C. is given (S210 of FIG. 25). At this time, although the conductive material that electrically couples the Cu pillar electrode PLBMP and the lead will be remelted, since in this second embodiment, the alloy part having a high melting point that does not allow it to remelt is formed in the inside of the conductive material, it is possible to improve electric coupling reliability between the Cu pillar electrode PLBMP and the lead.

Next, the multiple semiconductor devices PAC2 (refer to FIG. 24) can be obtained by performing package dicing of the wiring board WB (S211 of FIG. 25). Thus, the semiconductor device PAC2 in this second embodiment can be manufactured.

After being delivered to the customer, the manufactured semiconductor device PAC2 is mounted over the motherboard (S212 of FIG. 25). Also at this time, the solder reflow of about 260° C. is performed in a process of coupling the motherboard and the semiconductor device PAC2. At this time, the conductive material that electrically couples the Cu pillar electrode and the lead will be subjected to the remelting. However, since in this second embodiment, the alloy part having the high melting point that does not allow it to remelt is formed in the inside of the conductive material, it is possible to improve the electric coupling reliability between the Cu pillar electrode and the lead.

### <Modification>

Next, a modification of this second embodiment will be explained. In this second embodiment, as shown in FIG. 25, the alloying heat treatment is carried out after the first curing process and before the second flip-chip mounting process. In this case, the alloying heat treatment will be provided in a process before heat treatment processes each having possibility that the conductive material may be remelted (the second flip-chip mounting process, the BGA formation process, the mounting process over the motherboard). At this time, in the conductive material that electrically couples the Cu pillar electrode and the lead, the alloying heat treatment forms an alloy part comprised of the alloy of tin and copper inside this conductive material. Especially, in this second embodiment, this alloy part is formed so that it contacts both the Cu pillar electrode and the lead and so that the Cu pillar electrode and the lead are bound through the alloy part. Then, since the melting point of this alloy part is higher than a temperature of the heat treatment (solder reflow) shown by, for example, S207, S210, and S212 of FIG. 25, the alloy part will not be remelted. Therefore, even if the conductive material other than the alloy part flows out, the electric coupling between the Cu pillar electrode and the lead will be secured by the alloy part that will not be remelted. From this, according to this second embodiment, even in the case where a heat treatment (solder reflow) is performed after the electric coupling between the Cu pillar electrode and the lead is established through the conductive material, it is possible to improve the electric coupling reliability between the Cu pillar electrode and the lead.

However, the alloying heat treatment in, this second embodiment can be carried out after the second curing process shown in FIG. 25 and before the BGA formation process. In this case, there is a possibility that the conductive material that electrically couples the Cu pillar electrode of the first semiconductor chip and the lead of the wiring board may be remelted, for example, by a heat treatment in the second flip-chip mounting process. However, for example, the first solder and the second solder can be selected, for example, so that the melting point of the conductive material (first solder) for coupling the wiring board and the first semiconductor chip may become lower than the melting point of the conductive material (second solder) for coupling the first semiconductor chip and the second semiconductor chip. Thereby, by the heat treatment in the second flip-chip mounting process, it is possible to prevent the remelting of the conductive material (first solder) that electrically couples the Cu pillar electrode of the first semiconductor chip and the lead of the wiring board. That is, although the conductive material (solder) used, for example, in the BGA formation process and the mounting process over the motherboard is specified, for example, by the customer, offering no freedom of selection, regarding the conductive material used in the second flip-chip mounting process, a freedom of selection exists. Therefore, it is possible to prevent the conductive material (first solder) that electrically couples the Cu pillar electrode of the first semiconductor chip and the lead of the wiring board from remelting by selecting a second solder whose melting point is lower than that of the first solder, and thereby setting heat treatment temperature of the second flip-chip mounting process to be lower than the meting point of the first solder. This also makes it possible to carry out the alloying heat treatment after the second flip-chip mounting process, for example. Thus, in the case where the second solder whose melting point is lower than the melting point of the first solder is selected and the alloying heat, treatment is carried out after the second flip-chip mounting process, since a role of the alloy part formed in the first solder is reduced, it is also possible to acquire an effect that the heating time in the alloying heat treatment can be shortened.

Furthermore, even in the case where the conductive material (first solder) that electrically couples the Cu pillar electrode of the first semiconductor chip and the lead of the wiring board and the conductive material (second solder) that couples the first semiconductor chip and the second semiconductor chip are specified to be comprised of the same kind of solder, it is thought that if the alloying heat treatment is carried out after the second flip-chip mounting process, there will be comparatively few problems. This is because it is thought that occurrence of the coupling failure by the remelting is expanded by repeated remelting, and it is thought that one time melting in the second flip-chip mounting process does not leads to the coupling failure between the Cu pillar electrode of the first semiconductor chip and the lead of the wiring board. That is, even if the alloying heat treatment is carried out after the second flip-chip mounting process, it is considered that no problem exists as long as the alloying heat treatment has been already carried out at a stage where the BGA formation process and the mounting process over the motherboard are to be performed.

Incidentally, the alloying heat treatment that is a characteristic of this second embodiment can be carried out multiple-times in addition to being carried out only once. For example, the alloying heat treatment can be carried out after the first curing process shown in FIG. 25, and the alloying heat treatment can also be carried out also after the second curing process. In this case, it is not necessary for heating conditions in the alloying heat treatment after the first curing process and in the alloying heat treatment after the second curing process to be the same condition, and they may be different.

### Third Embodiment

In the first embodiment and the second embodiment, examples where the Cu pillar electrode PLBMP formed in the semiconductor chip CHP1 and the lead LD formed over the wiring board WB were electrically coupled to each other through the conductive material CM were explained. In a third embodiment, an example where the Cu pillar electrode PLBMP formed in the semiconductor chip CHP1 and a land formed over the wiring board WB are electrically coupled to each other through the conductive material CM will be explained. Especially, since there are a structure called solder mask defined (SMD) and a structure called non-solder mask defined (NSMD) in the lands formed over the wiring board, explanations are divided and given for the SMD and for the NSMD, respectively.

### <Application of Technical Idea to Land Comprised of SMD>

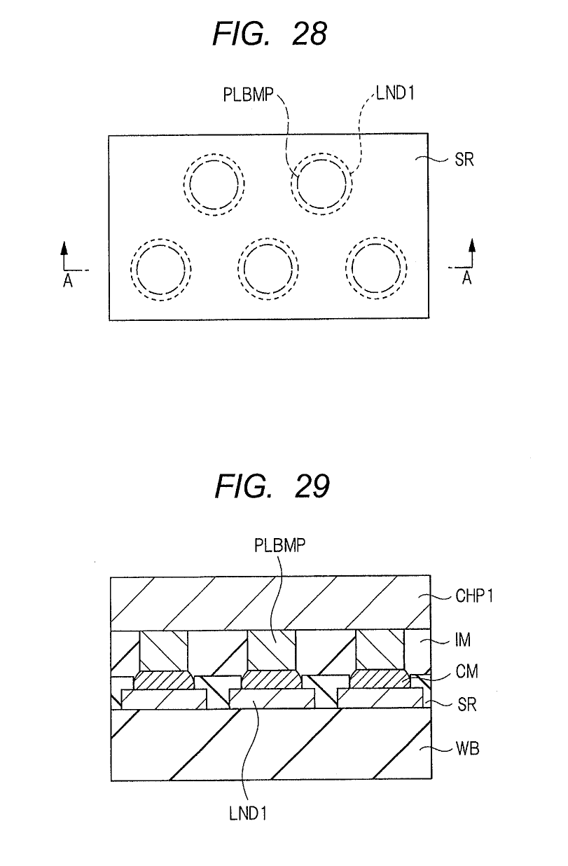

FIG. 28 is a schematic plan view showing an arrangement relationship among the solder resist SR formed over the wiring board, a land LND1 comprised of the SMD formed over the wiring board, and the Cu pillar electrode PLBMP formed in the semiconductor chip. FIG. 29 is a sectional view cut by the line A-A of FIG. 28. As shown in FIG. 29, the land LND1 is formed over the surface of the wiring board WB, and the solder resist SR is formed so as to cover an end of this land LND1. Then, an opening is formed in the solder resist SR and a part of the land LND1 is exposed from this opening. Thus, the SMD is characteristic in that a diameter of the land LND1 is made larger than a diameter of the opening. Therefore, the following will occur: the whole of the land LND1 is not exposed from the opening formed in the solder resist SR; only a central region of the land LND1 is exposed; and a peripheral region of the land LND1 is covered with the solder resist SR. That is, it can be said that the SMD is a configuration mode where the diameter of the land LND1 is larger than the diameter of the opening formed in the solder resist SR, and the opening is included by the land LND1 and a part of the land LND1 is exposed.

According to the SMD thus configured, since an outer periphery region of the land LND1 is covered with the solder resist SR, it has an advantage that adhesion of the wiring board WB and the land LND1 can be improved. That is, it can be said that the SMD is of a structure whereby peeling of the land LND1 from the wiring board WB hardly occurs.

In FIG. 29, the conductive material CM is filled in the opening formed in the solder resist SR, and the Cu pillar electrode PLBMP is arranged over this filled conductive material CM. That is, as shown in FIG. 29, the land LND1 comprised of the SMD formed over the wiring board WB and the Cu pillar electrode PLBMP formed in the semiconductor chip CHP1 are arranged so as to face each other, and are electrically coupled to each other through the conductive material CM. Then, the gap between the semiconductor chip CHP1 in which the Cu pillar electrode PLBMP is formed and the wiring board WB over which the solder resist SR is formed is filled with the insulating resin material IM.

Here, also in this third embodiment, the conductive material CM that couples the Cu pillar electrode PLBMP and the land LND1 will be remelted by a subsequent heat treatment that is represented, for example, by the solder reflow at the time of forming the solder balls and the solder reflow at the time of mounting the semiconductor device over the motherboard. When such remelting of the conductive material CM arises, there is a possibility that the electric coupling reliability of the Cu pillar electrode PLBMP and the land LND1 may decline.

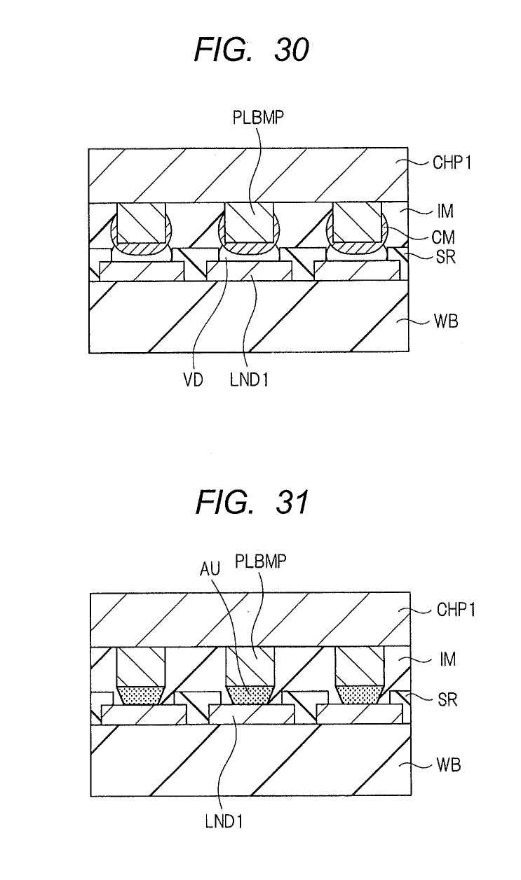

FIG. 30 is a schematic diagram corresponding to FIG. 29, and is a diagram showing a state after the conductive material CM is remelted. As shown in FIG. 30, when the conductive material CM that electrically couples the Cu pillar electrode PLBMP and the land LND1 is remelted, a phenomenon in which the conductive material CM that became the liquid creeps up the side face of the Cu pillar electrode PLBMP arises. As a result, since a part of the conductive material CM that electrically couples the Cu pillar electrode PLBMP and the land LND1 will be used for creep-up to the side face of the Cu pillar electrode PLBMP, the quantity of the conductive material CM formed between the Cu pillar electrode PLBMP and the land LND1 decreases. From this, as shown in FIG. 30, it is conceivable that a void VD occurs, for example, between the Cu pillar electrode PLBMP and the land LND1. If such a void VD occurs, the electric coupling between the Cu pillar electrode PLBMP and the land LND1 will be inhibited by the void VD, and there is a possibility that the coupling failure (open failure) may occur between the Cu pillar electrode PLBMP and the land LND1.

About this point, FIG. 31 is a sectional view for explaining an aspect of this third embodiment. As shown in FIG. 31, also in the case of the SMD, in the conductive material CM that electrically couples the Cu pillar electrode PLBMP and the land LND1, an alloy part AU comprised of the alloy of tin and copper is formed inside this conductive material CM. At this time, the alloy part AU contacts both the Cu pillar electrode PLBMP and the land LND1, and the Cu pillar electrode PLBMP and the land LND1 are bound through the alloy part AU. Thereby, also in the case of the SMD, it is possible to improve the electric coupling reliability between the Cu pillar electrode PLBMP and the land LND1.

This is because the conductive material CM is comprised of the solder containing tin, for example, and the alloy of tin and copper has a property of having a higher melting point than that of a solder containing no copper. That is, as shown in FIG. 31, in the SMD, the alloy part AU is formed and the melting point of this alloy part AU becomes higher than the melting point of the portion of the conductive material CM. This means that even when the conductive material CM is remelted by a heat treatment (solder reflow) that is performed in a subsequent process, for example, the alloy part AU is not remelted. As a result, in the alloy part AU, the creep-up phenomenon of the liquid to the side face of the Cu pillar electrode PLBMP resulting from the remelting does not arise. For this reason, it is possible to improve the electric coupling reliability between the Cu pillar electrode PLBMP and the land LND1 without the heat treatment that is performed in the subsequent process decreasing the quantity of the alloy part AU for coupling the Cu pillar electrode PLBMP and the land LND1.

### <Application of Technical Idea to Land Comprised of NSMD>

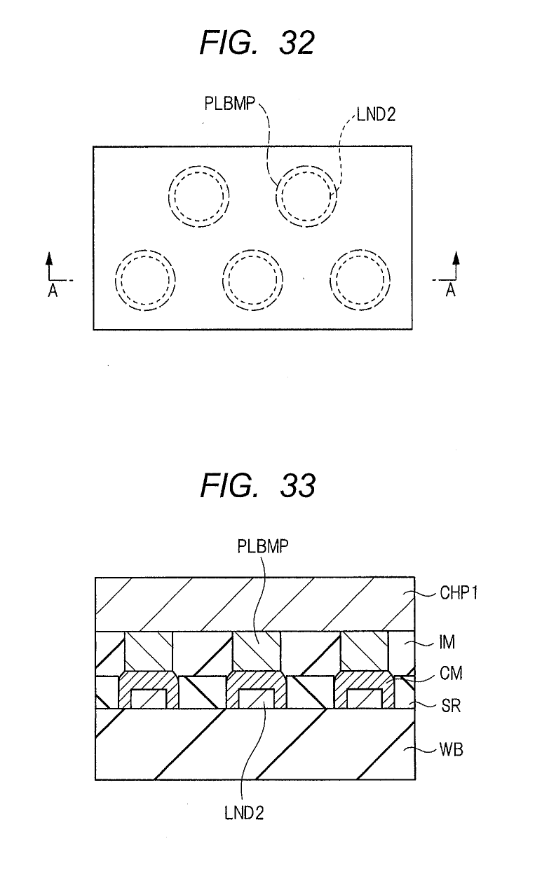

FIG. 32 is a schematic plan view showing an arrangement relationship among the solder resist SR formed over the wiring board, and a land LND2 comprised of NSMD formed over the wiring board, and the Cu pillar electrode PLBMP formed in the semiconductor chip. FIG. 33 is a sectional view cut by the line A-A of FIG. 32. As shown in FIG. 33, the surface of the wiring board WB is covered with the solder resist SR, and an opening is formed in this solder resist SR. Then, the land LND2 is arranged so as to be included by this opening. That is, although the opening and the land LND2 are formed in circular shapes, they are formed so that the diameter of the opening may become larger than a diameter of the land LND2. A configuration mode of such a land LND2 is NSMD. That is, it can be said that the NSMD is the configuration mode in which the diameter of the land LND2 is smaller than the diameter of the opening formed in the solder resist SR, and the whole of the land LND2 is included by the opening and the land LND2 is exposed.

According to the NSMD thus configured, since the whole of the land LND2 is exposed from the opening, not only a bottom of the land LND2 but also a side face thereof will be exposed from the opening (refer to FIG. 33). Therefore, the NSMD has advantages that an area exposed from the opening is large and an adhesion area with the conductive material CM that contacts a top of the land LND2 becomes large. From this, according to the NSMD, it will have an advantage that the adhesion between the land LND2 and the conductive material CM can be improved.

In FIG. 33, the conductive material CM is filled in the opening formed in the solder resist SR, and the Cu pillar electrode PLBMP is arranged over this conductive material CM that is filled. That is, as shown in FIG. 33, the land LND2 comprised of the NSMD formed over the wiring board WB and the Cu pillar electrode PLBMP formed in the semiconductor chip CHP1 are arranged so as to face each other, and are electrically coupled to each other through the conductive material CM. Then, the insulating resin material IM is filled in the gap between the semiconductor chip CHP1 in which the Cu pillar electrode PLBMP is formed and the wiring board WB over which the solder resist SR is formed.

Here, also in this third embodiment, the conductive material CM that couples the Cu pillar electrode PLBMP and land LND2 will be remelted by a subsequent heat treatment that is represented, for example, by the solder reflow at the time of forming the solder balls and the solder reflow at the time of mounting the semiconductor device over the motherboard. When such remelting of the conductive material CM arises, there is a possibility that the electric coupling reliability between the Cu pillar electrode PLBMP and the land LND2 may decline.

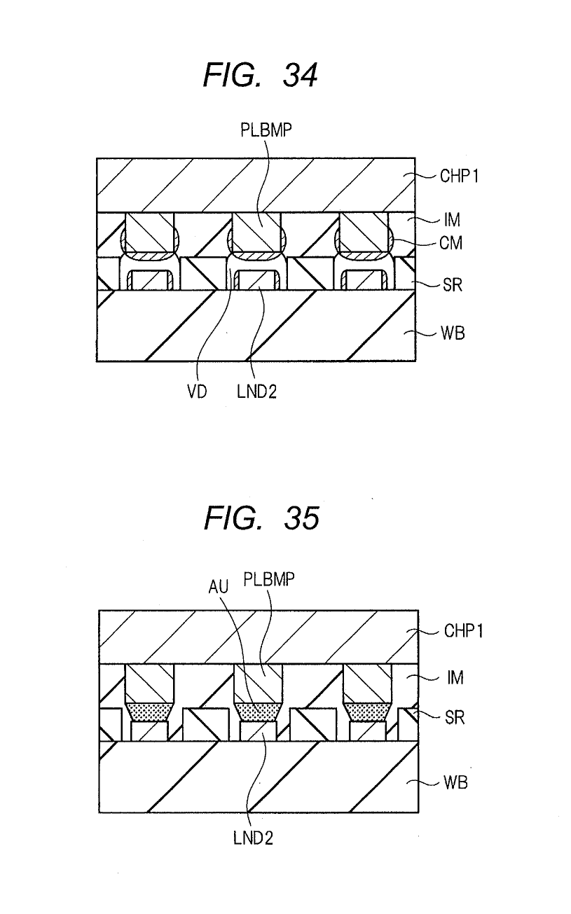

FIG. 34 is a schematic diagram corresponding to FIG. 33, and is a diagram showing a state after the conductive material CM is remelted. As shown in FIG. 34, when the conductive material CM that electrically couples the Cu pillar electrode PLBMP and the land LND2 is remelted, a phenomenon in which the conductive material CM that became the liquid creeps up the side face of the Cu pillar electrode PLBMP arises. As a result, since a part of the conductive material CM that electrically couples the Cu pillar electrode PLBMP and the land LND2 is used for creeping up the side face of the Cu pillar electrode PLBMP, the quantity of the conductive material CM formed between the Cu pillar electrode PLBMP and the land LND2 decreases. From this, for example, as shown in FIG. 34, it is conceivable that, void VD occurs between the Cu pillar electrode PLBMP and the land LND2. When such a void VD occurs, the electric coupling between the Cu pillar electrode PLBMP and the land LND2 will be inhibited by the void VD, and there is a possibility that an increase in electric resistance and the coupling failure (open failure) may occur between the Cu pillar electrode PLBMP and the land LND2.

About this point, FIG. 35 is a sectional view for explaining the aspect of this third embodiment. As shown in FIG. 35, also in the case of NSMD, in the conductive material CM that electrically couples the Cu pillar electrode PLBMP and the land LND2, the alloy part AU comprised of the alloy of tin and copper is formed inside this conductive material CM. At this time, the alloy part AU contacts both the Cu pillar electrode PLBMP and land LND2, and the Cu pillar electrode PLBMP and land LND2 are bound through the alloy part AU. Thereby, also in the case of the NSMD, it is possible to improve the electric coupling reliability between the Cu pillar electrode PLBMP and the land LND2.

This is because the conductive material CM is comprised of the solder containing tin, for example, the alloy of tin and copper has a property of having a higher melting point than that of the solder containing no copper. That is, as shown in FIG. 35, in the NSMD, the alloy part AU is formed and the melting point of this alloy part AU becomes higher than the melting point of the portion of the conductive material CM. This means that, for example, even when the conductive material CM is remelted by a heat treatment (solder reflow) performed in a subsequent process, the alloy part AU is not remelted. As a result, in the alloy part AU, the creep-up phenomenon of the liquid to the side face of the Cu pillar electrode PLBMP resulting from the remelting does not arise. For this reason, it is possible to improve the electric coupling reliability between the Cu pillar electrode PLBMP and the land LND2 without the heat treatment that is performed in the subsequent process decreasing the quantity of the alloy part AU for coupling the Cu pillar electrode PLBMP and the land LND2.

In the foregoing, although the invention made by the present inventors was concretely explained based on the embodiments, it goes without saying that the present invention is not limited to the embodiments and it can be modified variously within a range not deviating from the gist.

For example, although in the embodiments, the BGA was taken as an example and explained as the package mode of the semiconductor device, the technical idea in the embodiment is also applicable to a package mode called land grid array (LGA). This is because although in the case of the LGA, a process of forming solder balls like the BGA does not exist, a heat treatment (solder reflow) is applied also in the LGA when mounting the semiconductor device over the motherboard, and the conductive material may be remelted in this process. That is, also in the LGA, the technical idea in the embodiment is useful from the viewpoint of suppressing the coupling failure resulting from the remelting of the conductive material.

Moreover, although in the embodiments, the semiconductor device having the sealing, body was explained, the technical idea in the embodiment is also applicable to a package mode of a semiconductor device having no sealing body.

Furthermore, although in the embodiments, the configuration where the semiconductor chip was mounted over the wiring board was explained, the embodiment is not limited to this, and the technical idea in the embodiment is broadly applicable to a configuration of “Die to Die (D2D),” a configuration of “Die to Wafer (D2W),” and a configuration using a “silicon interposer.”

What is claimed is:

1. A semiconductor device, comprising:
(a) a first semiconductor chip in which a projection electrode containing copper is formed; and
(b) a substrate over which an electrode containing copper is formed, the projection electrode formed in the first semiconductor chip and the electrode formed over the substrate being electrically coupled to each other through a conductive material containing tin,
wherein an alloy part containing an alloy of tin and copper is formed in the conductive material, and
wherein the alloy part contacts both the projection electrode and the electrode, and the projection electrode and the electrode are bound through the alloy part.

2. The semiconductor device according to claim 1,
wherein the alloy part has a higher melting point than that of a portion other than the alloy part among portions of the conductive material.

3. The semiconductor device according to claim 1,
wherein the alloy part contains a single alloy phase.

4. The semiconductor device according to claim 1,
wherein the alloy part contains a plurality of different alloy phases.

5. The semiconductor device according to claim 4,
wherein the alloy part contains a Cu₃Sn phase and a Cu₆Sn₅ phase.

6. The semiconductor device according to claim 1,
wherein a portion other than the alloy part is formed in island shapes in the inside of the alloy part.

7. The semiconductor device according to claim 1,
wherein a volume ratio of a volume of the alloy part to a whole volume of the conductive material is more than or equal to 50%.

8. The semiconductor device according to claim 1,
wherein the projection electrode contains a copper layer containing copper as a main component and a nickel layer containing nickel as a main component, and
wherein the nickel layer is placed between the copper layer and the conductive material.

9. The semiconductor device according to claim 1,
wherein a distance between the projection electrode and the electrode is not less than 2 μm and not more than 10 μm.

10. The semiconductor device according to claim 1,
wherein the substrate is a wiring board over which wiring is formed.

11. The semiconductor device according to claim 10,
wherein the electrode is a lead or a land.

12. The semiconductor device according to claim 1,
wherein an insulating resin material for sealing a coupling portion of the projection electrode and the electrode is formed between the first semiconductor chip and the substrate.

13. The semiconductor device according to claim 1, further comprising:
a second semiconductor chip that is stacked and arranged to the first semiconductor chip.

14. A method for manufacturing a semiconductor device, comprising the steps of:
(a) preparing a first semiconductor chip in which a projection electrode containing copper is formed;
(b) preparing a substrate over which an electrode containing copper is formed;
(c) mounting the first semiconductor chip over the substrate by establishing electrical coupling between the projection electrode formed in the first semiconductor chip and the electrode formed over the substrate through a conductive material containing tin;
(d) heating the conductive material at a first temperature that is higher than the normal temperature and is lower than a melting point of the conductive material after the step (c); and
(e) dicing the substrate into individual chips after the step (d).

15. The method for manufacturing a semiconductor device according to claim 14,
wherein the step (c) includes a step of heating the conductive material at a second temperature higher than a melting point of the conductive material,
comprising the steps of:
(f) sealing a coupling portion between the protrusion electrode and the electrode with an insulating resin material; and
(g) heating the insulating resin material at a third temperature lower than the first temperature after the step (f), the step (f) and the step (g) being after the step (c) and before the step (d).

16. The method for manufacturing a semiconductor device according to claim 14, comprising a step of:
(h) providing an insulating resin material over the substrate before the step (c),
wherein the step (c) includes the steps of:
(c1) mounting the first semiconductor chip over the substrate so that the protrusion electrode may pierce through the insulating resin material; and
(c2) heating the conductive material second temperature higher than a melting temperature of the conductive material after the step (c1), and
wherein the method comprises a step of:
(i) heating the insulating resin material at a third temperature lower than the first temperature after the step (c) and before the step (d).

17. The method for manufacturing a semiconductor device according to claim 14,
wherein the step (d) is to heat the conductive material under a heating condition of 200° C. for 12 hours.

18. The method for manufacturing a semiconductor device according to claim 14, comprising a step of:
(j) stacking and arranging a second semiconductor chip to the first semiconductor chip while forming a coupling part for electrically coupling the first semiconductor chip and the second semiconductor chip between the first semiconductor chip and the second semiconductor chip after the step (c).

19. The method for manufacturing a semiconductor device according to claim 18,
wherein the step (d) is performed before the step (j).

20. The method for manufacturing a semiconductor device according to claim 18,
wherein the step (d) is performed after the step (j).
